(19) United States
(12) Patent Application Publication
(10) Pub. No.: US 2018/0072920 A1
(43) Pub. Date: Mar. 15, 2018

(54) GRAPHITE COMPOSITE FILM AND METHOD FOR PRODUCING SAME, AND HEAT-DISSIPATING PART

(71) Applicant: Kaneka Corporation, Osaka (JP)

(72) Inventors: Noriya Kaneda, Tochigi (JP); Hideaki Yano, Tochigi (JP); Yusuke Ohta, Tochigi (JP); Masaaki Nakamura, Tokyo (JP); Yasushi Nishikawa, Osaka (JP)

(73) Assignee: Kaneka Corporation, Osaka (JP)

(21) Appl. No.: 15/564,965

(22) PCT Filed: Apr. 8, 2016
(86) PCT No.: PCT/JP2016/061607

§ 371 Date: Oct. 6, 2017

(30) Foreign Application Priority Data
Apr. 10, 2015 (JP) 2015-081286

(51) Int. Cl. C09J 7/02; B32B 7/14; B32B 9/00; B32B 3/30; B32B 37/12; C01B 32/20; C09K 5/14; C09J 5/00; H05K 7/20

(52) U.S. Cl. CPC C09J 7/0217; B32B 7/14; B32B 9/007; B32B 3/30; B32B 37/12; C01B 32/20; C09J 2433/00; C09J 7/026; C09J 5/00; H05K 7/2039; C01P 2006/32; C09J 2203/326; C09J 2400/10; C09K 5/14

(57) ABSTRACT

Provided are: a graphite composite film that reduces bubble entrapment between itself and an adherend when bonded to the adherend without impairing its heat dissipation ability; and a method for producing the graphite composite film.

Specifically, provided are: a graphite composite film including a stack of a graphite film and an adhesive layer that has a projection/recess structure at its surface which faces away from the graphite film; and a method for producing the graphite composite film.

### TECHNICAL FIELD

The present invention relates to a graphite composite film, a method for producing the graphite composite film, and a heat dissipating component.

### BACKGROUND ART

Graphite films have excellent heat dissipation characteristics and thus are used as heat dissipating components in semiconductor devices included in various electronic devices such as computers or various electric devices, in some other heat generating components, and the like.

In such a heat dissipating component, a bonding agent or an adhesive such as an epoxy resin or an acrylic resin is used to join a graphite film to a housing of a heat generating component for excellent thermal conductivity of the graphite film to be utilized. For the purpose of reducing thermal resistance of a contact part between the graphite film and the heat generating component and thereby enhancing the heat dissipating effect of the graphite film in the heat dissipating component, there is disclosed a use of a graphite composite film which has an adhesive applied in a dotted pattern on the surface of a graphite layer (Patent Literature 1).

### CITATION LIST

### Patent Literature

### [Patent Literature 1]

Japanese Patent Application Publication Tokukai No. 2002-319653 (Publication date: Oct. 31, 2002)

### SUMMARY OF INVENTION

### Technical Problem

However, the technique disclosed in Patent Literature 1 still does not fully unitize the heat dissipation ability of the graphite film. The reason for this seems to be that, since the adhesive is applied in a dotted pattern, the graphite composite film and an adherend (i.e., heat generating component) only poorly adhere to each other and this inhibits heat transfer from the graphite composite film to the adherend, resulting in decrease of heat dissipation ability. On the other hand, a typical graphite composite film, which has an adhesive applied on an entire surface thereof, firmly adheres to the adherend (i.e., heat-generating component) and thus provides an excellent heat dissipation ability, but has an issue in that, when the graphite composite film is bonded to a heat generating component, air is trapped between the graphite composite film and the adherend, and the air forms bubbles. In particular, as a heat issue of electronic devices is becoming increasingly serious in recent years, graphite composite films for use in electronic devices are increasing in size. When such a large sheet is attached, bubble entrapment is a serious concern.

Bubbles may cause the following concerns: (i) the film becomes bad in appearance; (ii) an uneven surface resulting from bubbles physically obstructs other components, (iii) the film becomes poorly adhesive to an adherend, and (iv) heat is not smoothly transferred to the adherend; and/or the like.

Embodiments of the present invention are directed to a graphite composite film which, when bonded to an adherend, reduces bubble entrapment between itself and the adherend without impairing its heat dissipation ability, a method for producing the graphite composite film, and a heat dissipating component including the graphite composite film.

### Solution to Problem

The inventors studied hard to attain the above object, and found that, by arranging a graphite composite film including a graphite film and an adhesive layer in contact with the graphite film such that the area of the graphite film covered with an adhesive is 35% or more and 100% or less of the total area of the graphite film and that the adhesive layer has a projection/recess structure at its surface which faces away from the graphite film, it is possible to reduce bubble entrapment between an adherend and the graphite composite film when the graphite composite film is bonded to the adherend, without impairing the heat-dissipating ability of the graphite composite film. On the basis of this finding, the inventors accomplished the present invention. Specifically, the present invention encompasses the following aspects.

A graphite composite film in accordance with a first aspect of the present invention includes: a graphite film; and an adhesive layer in contact with the graphite film, wherein the area of the graphite film covered with an adhesive is 35% or more and 100% or less of the total area of the graphite film, and the adhesive layer has a projection/recess structure at a surface thereof which faces away from the graphite film.

A method for producing a graphite composite film in accordance with a second aspect of the present invention is a method for producing a graphite composite film that includes a graphite film and an adhesive layer in contact with the graphite film, the method including stacking the adhesive layer and the graphite film together in a manner such that: the area of the graphite film covered with an adhesive is 35% or more and 100% or less of the total area of the graphite film; and at least one surface of the adhesive layer, the at least one surface having a projection/recess structure thereon, faces away from the graphite film.

A method for producing a graphite composite film in accordance with a third aspect of the present invention is a method for producing a graphite composite film that includes a graphite film and an adhesive layer in contact with the graphite film, the method including: preparing the adhesive layer that has a projection/recess structure at at least one surface thereof by making an imprint of a projection/recess structure of a surface of a separator in the at least one surface of the adhesive layer; and stacking the adhesive layer and the graphite film together in a manner such that the at least one surface of the adhesive layer, the at least one surface having the projection/recess structure thereon, faces away from the graphite film.

A method for producing a graphite composite film in accordance with a fourth aspect of the present invention is a method for producing a graphite composite film that includes a graphite film and an adhesive layer in contact with the graphite film, the method including: forming a projection/recess structure at a surface of the adhesive layer by forming the adhesive layer on the graphite film which has a projection/recess structure at a surface thereof to thereby cause the projection/recess structure of the graphite film to appear at the surface of the adhesive layer.

A heat dissipating component in accordance with a fifth aspect of the present invention includes a graphite composite film, the graphite composite film including: a graphite film; and an adhesive layer in contact with the graphite film, wherein the area of the graphite film covered with an adhesive is 35% or more and 100% or less of the total area of the graphite film, and the adhesive layer has a projection/recess structure at a surface thereof which faces away from the graphite film.

### Advantageous Effects of Invention

A graphite composite film of an embodiment of the present invention can reduce bubble entrapment between itself and an adherend when bonded to the adherend, without impairing its heat dissipation ability.

According to a method for producing a graphite composite film of an embodiment of the present invention, it is possible to produce a graphite composite film that reduces bubble entrapment between itself and an adherend when bonded to the adherend, without impairing its heat dissipation ability.

According to a heat dissipating component of an embodiment of the present invention, it is possible to reduce bubble entrapment between an adherend and a graphite composite film when the graphite composite film is bonded to the adherend, without impairing the heat dissipation ability of the graphite composite film. Therefore, it is possible to obtain a heat dissipating component in which the following concerns are solved or reduced: (i) the film becomes bad in appearance; (ii) an uneven surface resulting from bubbles physically obstructs other components; (iii) the film becomes poorly adhesive to an adherend; and (iv) heat is not smoothly transferred to the adherend; and the like.

### BRIEF DESCRIPTION OF DRAWINGS

FIG. 1 shows specific examples of a projection/recess structure at a surface of an adhesive layer of an embodiment of the present invention. (a) of FIG. 1 illustrates separate island-like projections, (b) of FIG. 1 illustrates grooves in a lattice-like pattern, and (c) of FIG. 1 illustrates grooves in a striped pattern.

FIG. 2 schematically illustrates a configuration of a heat treatment apparatus for use in production of a graphite film in Examples of the present invention.

FIG. 3 is a cross-sectional view illustrating heating chambers of the heat treatment apparatus for use in production of a graphite film in Examples of the present invention.

FIG. 4 schematically illustrates how to set a carbonized film for graphitization in production of a graphite film in Examples of the present invention.

FIG. 5 schematically illustrates one example of a method of preparing an adhesive layer that has a projection/recess structure at its surface.

FIG. 6 schematically illustrates another example of a method of preparing an adhesive layer that has a projection/recess structure at its surface.

FIG. 7 schematically illustrates a further example of a method of preparing an adhesive layer that has a projection/recess structure at its surface.

FIG. 8 shows a structure of a system for use in performing a heat dissipation test on a graphite composite film in Examples of the present invention.

(a) and (b) of FIG. 9 show two kinds of cross-sectional structure of island-like projections in (a) of FIG. 1 along dash-dotted line A, grooves in a lattice-like pattern in (b) of FIG. 1 along dash-dotted line B, or grooves in a striped pattern in (c) of FIG. 1 along dash-dotted line C.

FIG. 10 shows how a heat dissipating component looks when viewed from the protective layer side of a graphite film, in Examples of the present invention.

FIG. 11 shows cross-sectional views of graphite composite films, in which an adhesive layer is composed of three layers, of embodiments of the present invention.

### DESCRIPTION OF EMBODIMENTS

The following describes embodiments of the present invention in detail. All academic and patent documents cited in the present specification are incorporated herein by reference. Further, any numerical range expressed as “A to B” in the present specification means “A or greater (A inclusive) and B or less (B inclusive)” unless otherwise stated.

[1] Graphite Composite Film

As described earlier, a typical graphite composite film, which has an adhesive applied on an entire surface thereof, firmly adheres to an adherend (i.e., heat generating component) and thus provides an excellent heat dissipation ability, but has an issue in that, when the graphite composite film is bonded to the heat generating component, air is trapped between the heat generating component and the adherend, and the air forms bubbles. One method to solve the bubble entrapment issue is to reduce adhesion density and/or adhesiveness between the adherend and the graphite composite film. A specific example of such a method is using an adhesive in a dotted pattern, using an adhesive having a weak adhesion force (weak peel strength), or the like. However, such methods sacrifice heat dissipation ability, which is the main objective of the graphite composite film. Under such circumstances, the inventors studied hard to achieve a graphite composite film that can prevent or reduce air trapping without impairing its heat-dissipating ability, and found that the following graphite composite film can prevent or reduce the air trapping without impairing the heat dissipation ability. That is, the graphite composite film includes: a graphite film; and an adhesive layer in contact with the graphite film, wherein the area of the graphite film covered with an adhesive is 35% or more and 100% or less of the total area of the graphite film, and the adhesive layer has a projection/recess structure at its surface which faces away from the graphite film. On the basis of this finding, the inventors accomplished the present invention. Specifically, a graphite composite film of an embodiment of the present invention includes: a graphite film; and an adhesive layer in contact with the graphite film, wherein the area of the graphite film covered with an adhesive is 35% or more and 100% or less of the total area of the graphite film, and the adhesive layer has a projection/recess structure at its surface which faces away from the graphite film.

(1-1) Adhesive Layer

An adhesive layer is a layer that resides on a graphite film and that connects between an adherend and the graphite connection film. The graphite composite film of an embodiment of the present invention may be any graphite composite film, provided that the area of the graphite film covered with an adhesive is 35% or greater and 100% or less of the total area of the graphite film and that the adhesive layer has a projection/recess structure at its surface which faces away from the graphite film. This makes it possible to reduce bubble entrapment between the adherend and the graphite composite film when the graphite composite film is bonded to the adherend, without impairing the heat dissipation ability of the graphite composite film. The inventors infer that the effects of an embodiment of the present invention are brought about in the following manner. First, since the adhesive layer of the graphite composite film has a projection/recess structure at its surface that is to make contact with an adherend, even if bubbles are trapped between the graphite composite film and the adherend when the graphite composite film and the adherend are bonded together, small spaces defined by the projection/recess structure facilitate escape of the bubbles (so-called, easy “air escape”). The inventors further infer that, since 35% to 100% of the total area of the graphite film of the graphite composite film of an embodiment of the present invention is covered with the adhesive, the adhesive existing in at least some of the small spaces defined by the projection/recess structure also serves to join the graphite composite film to the adherend after the bubbles escape from the small spaces. The result is that the graphite composite film and the adherend (e.g., a SUS housing, a plastic housing) firmly adhere to each other and that heat is transferred smoothly from the graphite composite film to the adherend. Therefore, heat dissipation ability is not lost.

In an embodiment of the present invention, the phrase “area of a graphite film covered with an adhesive” means the covered area of a graphite film covered with an adhesive contained in a layer for bonding to an adherend. Therefore, in a case where the adhesive layer is constituted by a plurality of layers, the phrase “area of a graphite film covered with an adhesive” means the covered area of a graphite film covered with an adhesive contained in one of the plurality of layers which is for bonding to an adherend and which is disposed oppositely from the graphite film (i.e., the outermost layer of the adhesive layer). It is noted that, in the case where the adhesive layer is constituted by a plurality of layers, the adhesive in the outermost layer does not make direct contact with the graphite film. In this case, an area of the graphite film corresponding to the region covered with the adhesive is referred to as “area of a graphite film covered with an adhesive”.

In the graphite composite film of an embodiment of the present invention, the area of the graphite film covered with an adhesive is 35% or greater and 100% or less of the total area of the graphite film. Specifically, the present invention encompasses: arrangements in which the area of the graphite film covered with an adhesive is 100% of the total area of the graphite film; and arrangements in which the area of the graphite film covered with an adhesive is 35% or greater and less than 100% of the total area of the graphite film.

A case where the area of the graphite film covered with an adhesive is 100% of the total area of the graphite film is such that, as illustrated in (b) of FIG. 9 for example, the adhesive contained in the adhesive layer entirely covers the graphite film and that the adhesive layer has a projection/recess structure at its surface which faces away from the graphite film.

A case where the area of the graphite film covered with an adhesive is 35% or greater and less than 100% of the total area of the graphite film is such that, as illustrated in (a) of FIG. 9 for example, there are some portions in which the graphite film is exposed and not covered with the adhesive contained in the adhesive layer, and that the adhesive layer has a projection/recess structure at its surface which faces away from the graphite film. In this case, the area of the graphite film covered with an adhesive is preferably 35% or greater and 90% or less, more preferably 50% or greater and 85% or less, of the total area of the graphite film. An arrangement in which the percentage of the area of the graphite film covered with an adhesive relative to the total area of the graphite film falls within the above range is preferred, because this achieves good contact between the graphite composite film and the adherend and thus achieves excellent heat conduction, and reduces bubble entrapment between the adherend and the graphite composite film when the graphite composite film is bonded to the adherend without impairing the heat dissipation ability of the graphite composite film. The good contact with the adherend also provides excellent adhesion force.

The adhesive layer of an embodiment of the present invention may have any structure at its surface that is in contact with the graphite film, provided that the adhesive layer has a projection/recess structure at its surface which faces away from the graphite film. That is, the adhesive layer may or may not have a projection/recess structure at its surface that is in contact with the graphite film.

(1-1-1) Projection/Recess Structure

In an embodiment of the present invention, the phrase “having a projection/recess structure” is not limited to a particular structure, provided that the surface is not flat and has unevenness. For example, the surface with a projection/recess structure of the adhesive layer preferably has a surface roughness that is 0.19 μm or greater and 10 μm or less in Ra and that is 1.6 μm or greater and 100 μm or less in Rz, more preferably has a surface roughness that is 0.19 μm or greater and 1.0 μm or less in Ra and that is 1.6 μm or greater and 10.0 μm or less in Rz, particularly preferably has a surface roughness that is 0.35 μm or greater and 0.70 μm or less in Ra and that is 2.5 μm or greater and 6.0 μm or less in Rz. Alternatively, the surface with a projection/recess structure of the adhesive layer has a surface roughness of preferably 0.19 μm or greater and 10 μm or less in Ra, more preferably 0.19 μm or greater and 1.0 μm or less in Ra, even more preferably 0.35 μm or greater and 0.70 μm or less in Ra. Alternatively, the surface with a projection/recess structure of the adhesive layer has a surface roughness of more preferably 1.6 μm or greater and 100 μm or less in Rz, even more preferably 1.6 μm or greater and 10.0 μm or less in Rz, particularly preferably 2.5 μm or greater and 6.0 μm or less in Rz. An arrangement in which the surface with a projection/recess structure has a surface roughness falling within the above range is preferred, because this reduces bubble entrapment between the adherend and the graphite composite film when the graphite composite film is bonded to the adherend without impairing the heat dissipation ability of the graphite composite film. As used herein, the term “surface roughness” denotes a value obtained in accordance with the measurement method described in Examples.

The projection/recess structure is not limited to a particular shape, and may have any shape. The projection/recess structure may have a nonuniform shape formed from a mixture of at least some of projections and recesses of various shapes. However, from the viewpoint of appearance and productivity, the projection/recess structure is more preferably formed from projections and/or recesses of a uniform shape. The uniform shape gives good appearance, and uniform pattern is suitable for mass-production of films.

The projection/recess structure is not limited to a particular shape also when the projection/recess structure is formed from projections and/or recesses of a uniform shape. For example, the projection/recess structure may be defined by grooves in a lattice-like pattern or a striped pattern or by separate island-like projections.

<Separate Island-Like Projections>

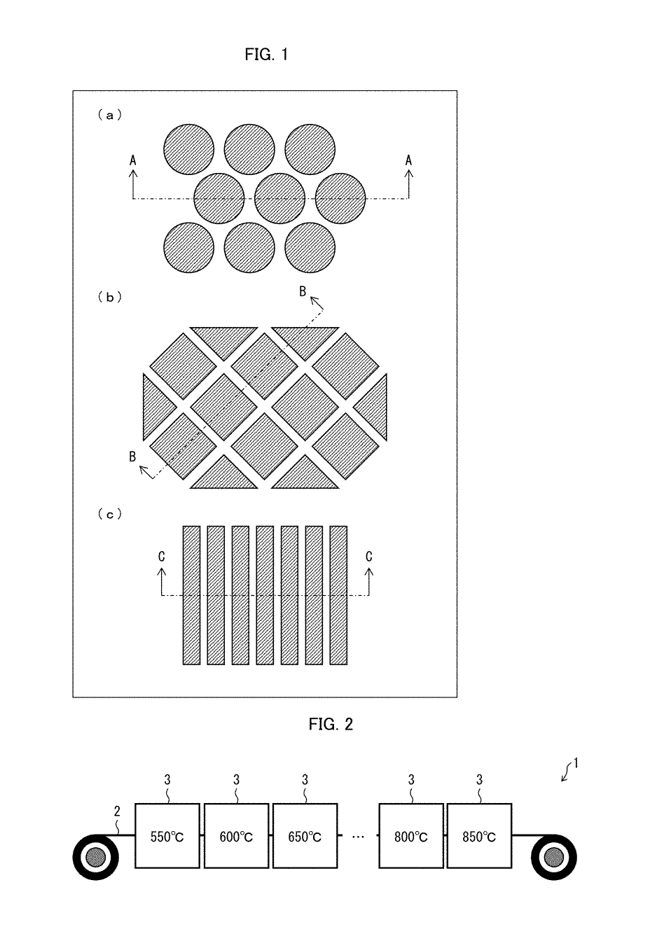

FIG. 1 shows specific examples of the projection/recess structure. (a) of FIG. 1 is a plan view of separate island-like projections viewed from above. In (a) of FIG. 1, the island-like projections are represented by hatching. Although the island-like projections have a circular shape in (a) of FIG. 1, the projections are not limited to a circular shape and may have any shape. For example, the projections may have an oval shape, a polygonal shape, a rod-like shape, a strip-like shape, an irregular shape, or the like. The polygonal shape may be a triangle shape, a quadrangular shape (such as a square shape, a rectangle shape, or a rhombus shape), a pentagon shape, a hexagon shape, or the like.

The island-like projections illustrated in (a) of FIG. 1 may have a cross section as shown in (a) of FIG. 9 or (b) of FIG. 9 when cut along dash-dotted line A. That is, the bottom of each recess may or may not have an adhesive thereon. Alternatively, the cross-section may be a mixture of the structures illustrated in (a) and (b) of FIG. 9. In the examples discussed above, the island-like projections constitute the projections of the projection/recess structure and the rest constitute the recesses of the projection/recess structure.

(a) of FIG. 9 shows an example of an arrangement in which the area of the graphite film covered with an adhesive is 35% or greater and less than 100% of the total area of the graphite film. As illustrated in (a) of FIG. 9, in this example, a graphite film 41 has exposed portions not covered with an adhesive 42. In the example shown in (a) of FIG. 9, the exposed portions of the graphite film 41 not covered with the adhesive 42 correspond to bottoms 39 of the recesses. This structure is such that the height h of an island-like projection is equal to the thickness of the adhesive layer (or a second adhesive layer if the adhesive layer has a three-layer structure as will be described later) and, in the recesses in the adhesive layer, there is no adhesive and the graphite film 41 (or a base if the adhesive layer has a three-layer structure as will be described later) is exposed. In other words, the adhesive layer includes adhesive parts disposed on the graphite film 41, and the projection/recess structure at a surface of the adhesive layer includes projections which are constituted by the adhesive parts and recesses in which there is no adhesive and the graphite film 41 is exposed. Such an arrangement is preferred, because this more efficiently reduces bubble entrapment between the adherend and the graphite composite film when the graphite composite film is bonded to the adherend.

(b) of FIG. 9 shows an example of an arrangement in which the area of the graphite film covered with an adhesive is 100% of the total area of the graphite film. As illustrated in (b) of FIG. 9, in this example, a graphite film 41 is entirely covered with an adhesive 42 and an adhesive layer has a projection/recess structure at its surface which faces away from the graphite film 41. This structure is such that the height h of an island-like projection is less than the thickness of the adhesive layer (or a second adhesive layer if the adhesive layer has a three-layer structure as will be described later) and that an adhesive is present between a bottom 39 of each recess in the adhesive layer and the graphite film 41. Such a structure is preferred, because this more efficiently reduces bubble entrapment between the adherend and the graphite composite film when the graphite composite film is bonded to the adherend and, after that, the adhesive between the graphite film 41 and the bottom 39 of the recess in the adhesive layer helps join together the adherend and the graphite composite film.

Top faces 38 of the island-like projections are more preferably flush with each other, from the viewpoint of excellent adhesiveness. The top faces 38 of the island-like projections are more preferably flat faces, from the same point of view. Although the island-like projections are arranged regularly in (a) of FIG. 1 and (a) and (b) of FIG. 9, they may be arranged in an irregular manner. Furthermore, although the island-like projections are of a uniform shape in (a) of FIG. 1 and (a) and (b) of FIG. 9, they may have different shapes. The bottoms 39 of the recesses are more preferably, but not particularly limited to be, flush with each other. The bottoms 39 more preferably have a flat surface.

The island-like projections may have a side wall 40 that is substantially perpendicular to or at an angle to the bottoms 39 or the top faces 38. In a case where the side wall 40 is at an angle to the bottoms 39 or the top faces 38, the angle α between the side wall 40 of a projection and a bottom 39 is preferably 60° or greater and 150° or less, more preferably 90° or greater and 120° or less. Note, however, that the present embodiment also encompasses a structure in which the side wall 40 of the island-like projection is connected to the bottom 39 or the top face 38 by a curved face without necessarily forming a sharp angle α. The height h of the island-like projection (i.e., the distance between the bottom 39 and the top face 38) is preferably 0.1 μm or greater and 20 μm or less, more preferably 0.5 μm or greater and 5 μm or less, even more preferably 1.0 μm or greater and 3.0 μm or less. The island-like projections having a height h within the above range are preferred, because this more suitably reduces bubble entrapment between the adherend and the graphite composite film when the graphite composite film is bonded to the adherend without impairing the heat dissipation ability of the graphite composite film.

In a case where the island-like projections are regularly arranged projections in the form of polygonal, rod-shaped, and/or strip-shaped islands, the distance between the mutually facing edges of adjacent ones of the projections (such a distance hereinafter may be referred to as “distance between island-like projections”) is preferably 0.01 mm or greater, more preferably 0.1 mm or greater. The upper limit of the distance is preferably 2.0 mm or less, more preferably 0.88 mm or less, even more preferably 0.5 mm or less. For example, in a case where the island-like projections are in the form of a quadrangle, it is preferable that the distance between the mutually facing sides of quadrangles of adjacent island-like projections fall within the above range. The distance within the above range is preferred, because this reduces bubble entrapment between the adherend and the graphite composite film when the graphite composite film is bonded to the adherend without impairing the heat dissipation ability of the graphite composite film.

<Grooves in a Lattice-Like Pattern>

(b) of FIG. 1 is a plan view illustrating grooves in a lattice-like pattern viewed from above. In (b) of FIG. 1, the grooves in a lattice-like pattern are represented by unhatched areas. Although the grooves are in a square lattice-like pattern in (b) of FIG. 1, the lattice is not limited to a square lattice and may be any kind of lattice. For example, the lattice may be a triangular lattice, a rectangular lattice, a rhombus lattice, a polygonal lattice, or the like. Alternatively, the lattice may be a mixture of different shapes of lattices. Furthermore, the grooves are not limited to straight grooves and may be curved grooves.

The grooves in a lattice-like pattern illustrated in (b) of FIG. 1 may have a cross section as shown in (a) of FIG. 9 or (b) of FIG. 9, or may have a mixture of the structures of (a) and (b) of FIG. 9, when cut along dash-dotted line B, as with the separate island-like projections. In the example where the grooves are in a lattice-like pattern, the grooves in a lattice-like pattern correspond to the recesses of the projection/recess structure and the rest constitute the projections of the projection/recess structure.

(a) and (b) of FIG. 9 have already been described in the <Separate island-like projections> section. In the example where the grooves are in a lattice-like pattern and have a structure of (a) of FIG. 9, the grooves in a lattice-like pattern have a depth h that is equal to the thickness of the adhesive layer (or a second adhesive layer if the adhesive layer has a three-layer structure as will be described later) and, in the recesses in the adhesive layer, there is no adhesive and the graphite film 41 (or a base if the adhesive layer has a three-layer structure as will be described later) is exposed. Such a structure is preferred, because this more efficiently reduces bubble entrapment between the adherend and the graphite composite film when the graphite composite film is bonded to the adherend.

Alternatively, in the example where the grooves are in a lattice-like pattern and have a structure of (a) of FIG. 9, the depth h of a groove is less than the thickness of the adhesive layer (or a second adhesive layer if the adhesive layer has a three-layer structure as will be described later) and an adhesive is present between a bottom 39 of each recess in the adhesive layer and the graphite film 41. Such a structure is preferred, because this more efficiently reduces bubble entrapment between the adherend and the graphite composite film when the graphite composite film is bonded to the adherend and, after that, the adhesive between the graphite film 41 and the bottom 39 of the recess in the adhesive layer helps join together the adherend and the graphite composite film.

The intervening projections between the grooves more preferably have top faces flush with each other, from the viewpoint of excellent adhesiveness. The top faces are more preferably flat faces from the same point of view.

The grooves in a lattice-like pattern have a pitch of preferably 0.05 mm or greater and 2.0 mm or less, more preferably 0.1 mm or greater and 1.0 mm or less, even more preferably 0.15 mm or greater and 0.40 mm or less. It is noted that the pitch of the grooves in a lattice-like pattern denotes the distance between adjacent intersections of grooves that constitute a lattice. In a case where the grooves have a certain width, the intersection means the intersection of the centerlines of the grooves. For example, in a case where the grooves are in a square lattice-like pattern or a rhombus lattice-like pattern, the pitch corresponds to the length of one side of a square or a rhombus of the lattice defined by the centerlines of grooves. In a case where the grooves are in a rectangular lattice-like pattern, there are two kinds of pitch: the length of the long side of the rectangle; and the length of the short side of the rectangle. Therefore, in the case of a rectangular lattice-like pattern, it is preferable that both of these two kinds of pitch fall within the above range. The pitch of the grooves in a lattice-like pattern falling within the above range is preferred, because this more suitably reduces bubble entrapment between the adherend and the graphite composite film when the graphite composite film is bonded to the adherend without impairing the heat dissipation ability of the graphite composite film.

The grooves have a depth of preferably 0.1 μm or greater and 20 μm or less, more preferably 0.3 μmm or greater and 5 μm or less, even more preferably 0.5 μm or greater and 1.9 μm or less. The grooves are not particularly limited also as to their width, and may have a width of preferably 0.001 mm or greater and 2 mm or less, more preferably 0.01 mm or greater and 0.05 mm or less. The grooves in a lattice-like pattern having a depth and a width within the above ranges are preferred, because this more suitably reduces bubble entrapment between the adherend and the graphite composite film when the graphite composite film is bonded to the adherend without impairing the heat dissipation ability of the graphite composite film.

The grooves are not particularly limited as to their shape as well, and may have a cross section of, for example, a V-shape, a U-shape, a quadrangle shape, or the like. The groove's cross section is not limited to a perfect V-shape, a perfect U-shape, or a perfect quadrangle shape and may have an irregular shape which is a modified version of any of the above shapes. It is noted that the separate island-like projections and the grooves in a lattice-like pattern sometimes result in the same projection/recess structure.

<Grooves in a Striped Pattern>

(c) of FIG. 1 is a plan view illustrating grooves in a striped pattern viewed from above. In an embodiment of the present invention, the term “striped pattern” denotes stripes as illustrated in (c) of FIG. 1 and is intended to exclude cross stripes. In (c) of FIG. 1, the grooves in a striped pattern are represented by unhatched areas. Although the grooves in a striped pattern are straight grooves in (b) of FIG. 1, the grooves are not limited to straight grooves and may be curved grooves. Furthermore, although the grooves are equally spaced in (c) of FIG. 1, the grooves do not have to be equally spaced.

The grooves in a striped pattern illustrated in (c) of FIG. 1 may have a cross section as shown in (a) of FIG. 9 or (b) of FIG. 9, or may have a mixture of the structures of (a) and (b) of FIG. 9, when cut along dash-dotted line C, as with the separate island-like projections. In the example where the grooves are in a striped pattern, the grooves in a striped pattern correspond to the recesses of the projection/recess structure and the rest constitute the projections of the projection/recess structure.

(a) and (b) of FIG. 9 have already been described in the <Separate island-like projections> section. In the example where the grooves are in a striped pattern and have a structure shown in (a) of FIG. 9, the grooves in a striped pattern have a depth h that is equal to the thickness of the adhesive layer (of a second adhesive layer if the adhesive layer has a three-layer structure as will be described later) and, in the recesses in the adhesive layer, there is no adhesive and the graphite film 41 (or a base if the adhesive layer has a three-layer structure as will be described later) is exposed. Such a structure is preferred, because this more efficiently reduces bubble entrapment between the adherend and the graphite composite film when the graphite composite film is bonded to the adherend.

Furthermore, in the example where the grooves are in a lattice-line pattern and have a structure of (a) of FIG. 9, the grooves in a striped pattern have a depth h that is less than the thickness of the adhesive layer (or a second adhesive layer if the adhesive layer has a three-layer structure as will be described later) and the adhesive is present between a bottom 39 of each recess in the adhesive layer and the graphite film 41 (or a base if the adhesive layer has a three-layer structure as will be described later). Such a structure is preferred, because this more efficiently reduces bubble entrapment between the adherend and the graphite composite film when the graphite composite film is bonded to the adherend and, after that, the adhesive between the graphite film 41 and the bottom 39 of the recess in the adhesive layer helps join together the adherend and the graphite composite film.

The intervening projections between the grooves more preferably have top faces flush with each other from the view point of excellent adhesiveness. The top faces are more preferably flat faces from the same point of view. The grooves in a striped pattern have a pitch of preferably 0.1 mm or greater and 2.0 mm or less, more preferably 0.5 mm or greater and 1.0 mm or less. As used herein, the pitch of the grooves in a striped pattern means the distance between grooves. In a case where the grooves have a certain width, the distance means the distance between the centerlines of the grooves. The grooves in a striped pattern may have a depth, a width, and a shape that are similar to those of the grooves in a lattice-like pattern.

<Thickness of Adhesive Layer>

The adhesive layer has a thickness of preferably 1.00 μm or greater and 20.00 μm or less, more preferably 2.00 μm or greater and 10.00 μm or less, even more preferably 3.00 μm or greater and 7.00 μm or less. The adhesive layer having a thickness of 1.00 μm or greater is preferred, because such an adhesive layer is thick enough to bond to the adherend. The adhesive layer having a thickness of 20.00 μm or less is preferred, because this reduces thermal resistance when heat diffused in the graphite film is transferred to the adherend through the adhesive. As used herein, the term “thickness of an adhesive layer” denotes the thickness of a layer that contains an adhesive and that is for bonding to the adherend. That is, in a case where the adhesive layer is constituted by a plurality of layers, the term “thickness of an adhesive layer” denotes the thickness of one of the plurality of layers which contains the adhesive, which is for bonding to the adherend, and which is disposed oppositely from the graphite film (i.e., the thickness of the outermost layer of the adhesive layer). For example, in a case where the adhesive layer has a three-layer structure as will be described later, the “thickness of an adhesive layer” denotes the thickness of a second adhesive layer, which will be described later.

The thickness of the adhesive layer means a value obtained by measurement in accordance with the method which will be described later in Examples. Furthermore, in the present specification, the thicknesses of a graphite film (GS), an adhesive layer (when the adhesive layer has a three-layer structure, the thicknesses of these layers), a graphite composite film, an application layer, a protective layer, and the like also denote values obtained by measurement in accordance with the method which will be described later in Examples.

(1-1-2) Structure of Adhesive Layer

The adhesive layer is not particularly limited as to its structure, provided that the area of the graphite film covered with an adhesive is 35% or more and 100% or less of the total area of the graphite film and that the adhesive layer has a projection/recess structure at its surface which faces away from the graphite film. The adhesive layer may have a single-layer structure or a multilayer structure. The adhesive layer preferably has a three-layer structure that includes a first adhesive layer, a base, and a second adhesive layer. When the adhesive layer includes the base, the graphite composite film becomes more resilient. In addition, the base prevents or reduces the breakage of the graphite film, and thus prevents or reduces delamination of the graphite film when the attached graphite film is to be removed. This makes it possible to easily remove and re-attach the graphite film.

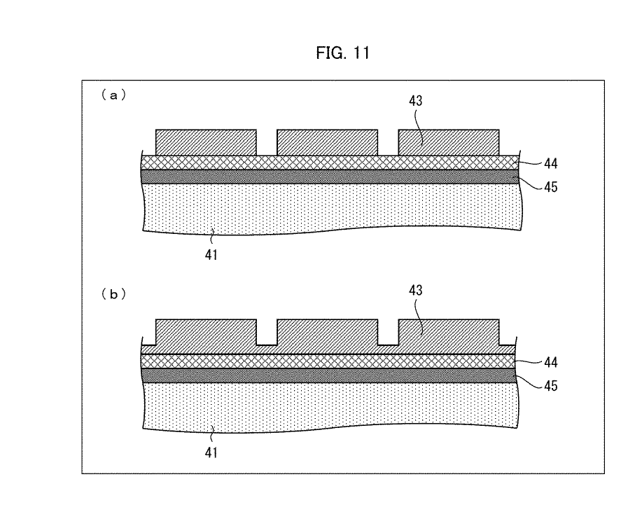

FIG. 11 schematically illustrates cross sections of examples of a graphite composite film which has an adhesive layer composed of three layers. (a) of FIG. 11 shows an example in which the area of the graphite film covered with an adhesive is 35% or more and less than 100% of the total area of the graphite film, and (b) of FIG. 11 shows an example in which the area of the graphite film covered with an adhesive is 100% of the total area of the graphite film.

As illustrated in (a) and (b) of FIG. 11, a first adhesive layer 45, a base 44, and a second adhesive layer 43 are stacked on a graphite film 41 in this order from the graphite film 41. Therefore, the adhesive layer may be such that the second adhesive layer 43 has a projection/recess structure at its surface which faces away from the base 44. The description for the projection/recess structure of the adhesive layer composed of three layers is omitted here, because it has been already described in the “(1-1-1) Projection/recess structure” section. Note, however, that it is assumed in the “(1-1-1) Projection/recess structure” section that the “graphite film 41” is read as “base” and the “adhesive layer” is read as “second adhesive layer”.

Also in the case where the adhesive layer is composed of such three layers, the area of the graphite film covered with an adhesive only needs to fall within a range of 35% or greater and 100% or less of the total area of the graphite film. Note here that the area of the graphite film covered with an adhesive in the case where the adhesive layer is composed of three layers means the area of the graphite film covered with an adhesive contained in the second adhesive layer (i.e., one of the three layers that is disposed oppositely from the graphite film and that is for bonding to the adherend). In an embodiment of the present invention, it is preferable that the graphite film and the base be equal in area to each other. In this case, the area of the graphite film covered with an adhesive contained in the second adhesive layer can be regarded as the area of the base covered with the adhesive contained in the second adhesive layer.

That is, in other words, the area of the base covered with the adhesive contained in the second adhesive layer is preferably 35% or greater and 100% or less of the total area of the base. With this arrangement, bubbles that would be trapped between the graphite composite film and the adherend when the graphite composite film and the adherend are bonded together can escape along small spaces defined by the projection/recess structure, and thereafter the adhesive in those spaces helps join the graphite composite film to the adherend. Therefore, heat transfer from the graphite composite film to the adherend is smooth and thus the heat dissipation ability is not impaired.

Specifically, the area of the base covered with the adhesive contained in the second adhesive layer may be 100% of the total area of the base or may be 35% or greater and less than 100% of the total area of the base.

An arrangement in which the area of the base covered with an adhesive is 100% of the total area of the base is the same as that of the graphite film and the adhesive illustrated as an example in (b) of FIG. 9, except that the graphite film in (b) of FIG. 9 is replaced by the base. Therefore, the description for such an arrangement is omitted here. Specifically, as illustrated in (b) of FIG. 11, the base 44 is entirely covered with the adhesive contained in the second adhesive layer 43, and the second adhesive layer 43 has a projection/recess structure at its surface which faces away from the base 44.

An arrangement in which the area of the base covered with an adhesive is 35% or greater and less than 100% of the total area of the base is the same as that of the graphite film and the adhesive illustrated as an example in (a) of FIG. 9, except that the graphite film in (a) of FIG. 9 is replaced by the base. Therefore, the description for such an arrangement is omitted here. Specifically, as illustrated in (a) of FIG. 11, the base 44 is partially exposed and not covered with the adhesive contained in the second adhesive layer 43, and the second adhesive layer 43 has a projection/recess structure at its surface which faces away from the base. In this case, the area of the base covered with an adhesive is more preferably 35% or greater and 90% or less, even more preferably 50% or greater and 85% or less, of the total area of the graphite film. An arrangement in which the percentage of the area of the base covered with an adhesive relative to the total area of the base falls within the above range is preferred, because this achieves good contact between the adhesive layer and the adherend and thus achieves excellent heat conduction, and reduces bubble entrapment between the adherend and the graphite composite film when the graphite composite film is bonded to the adherend without impairing the heat dissipation ability of the graphite composite film. The good contact with the adherend also provides excellent adhesion force.

In other words, in the case where the adhesive layer is composed of three layers, the adhesive may or may not be present at the bottoms of the recesses of the projection/recess structure of the second adhesive layer. However, from the viewpoint of more efficiently reducing bubble entrapment, it is more preferable that no adhesive is present at the bottoms of the recesses of the projection/recess structure. In this case, in the recesses of the projection/recess structure, the base is exposed. That is, the area of the base covered with the adhesive contained in the second adhesive layer is more preferably 35% or greater and less than 100% of the total area of the base. This arrangement is such that the second adhesive layer is constituted by adhesive parts disposed on the base and that the projections of the projection/recess structure at the surface of the adhesive layer are constituted by the adhesive parts and, in the recesses of the projection/recess structure, there is no adhesive and the base is exposed. Such an arrangement is preferred, because this more efficiently reduces bubble entrapment between the adherend and the graphite composite film when the graphite composite film is bonded to the adherend.

In a case where the adhesive parts are regularly arranged projections in the form of polygonal, rod-shaped, and/or strip-shaped islands, the distance between the mutually facing edges of adjacent island-like projections is preferably 0.01 mm or greater, more preferably 0.1 mm or greater. The upper limit of the distance is preferably 2.0 mm or less, more preferably 0.88 mm or less, even more preferably 0.5 mm or less. An arrangement in which the distance between the mutually facing edges of adjacent island-like projections (adhesive parts) is 0.01 mm or greater is preferred, because this more efficiently reduces bubble entrapment. Furthermore, the distance falling within the above range is preferred because this reduces bubble entrapment between the adherend and the graphite composite film when the graphite composite film is bonded to the adherend without impairing the heat dissipation ability of the graphite composite film.

The adhesive parts occupy preferably 35% or greater and 90% or less, more preferably 50% or greater and 85% or less of the total area of the adhesive layer. An arrangement in which the percentage of the area of the adhesive layer occupied by the adhesive parts relative to the total area of the adhesive layer falls within the above range is preferred, because this achieves good contact with the adherend and thus achieves excellent heat conduction, and reduces bubble entrapment between the adherend and the graphite composite film when the graphite composite film is bonded to the adherend without impairing the heat dissipation ability of the graphite composite film. The good contact with the adherend also provides excellent adhesion force.

It is noted that the area of the graphite film covered with an adhesive contained in the first adhesive layer which is in contact with the graphite film may be 100% of the total area of the graphite film or may be 30% or greater and less than 100% of the total area of the graphite film. It is more preferable that this covered area be 100%. This achieves a graphite composite film which maintains its heat dissipation ability.

The adhesive layer, which includes the first adhesive layer, the base, and the second adhesive layer, is not particularly limited as to the thickness of each layer thereof. The first adhesive layer has a thickness of preferably 0.1 μm or greater and 20 μm or less, more preferably 0.5 μm or greater and 5 μm or less, even more preferably 1 μm or greater and 3 μm or less. The base has a thickness of preferably 0.5 μm or greater and 10 μm or less, more preferably 1 μm or greater and 5 μm or less. The second adhesive layer has a thickness of preferably 0.1 μm or greater and 20 μm or less, more preferably 0.5 μm or greater and 5 μm or less, even more preferably 1 μm or greater and 3 μm or less.

The material for the adhesive for use in the adhesive layer may be, for example, an acrylic-based adhesive, a silicone-based adhesive, a rubber-based adhesive, and/or the like. These materials are highly heat resistant and therefore achieve sufficient long-term reliability even when used in combination with a heat generating component and/or a heat dissipating component. Furthermore, these materials are reusable and have excellent long-term reliability and therefore provide excellent reusability and removability. In the case where the adhesive layer is composed of three layers, the first adhesive layer and the second adhesive layer may be made of the same material or different materials. The present technique is also applicable to adhesives for use with heat, such as polyimide and epoxy adhesives.

The base is preferably a polymeric film, which is, for example, a polymeric film that contains at least one selected from the group consisting of polyimide-based resins, polyethylene terephthalate (PET)-based resins, polyphenylene sulfide (PPS)-based resins, polyethylene naphthalate (PEN)-based resins, and polyester-based resins. Of these, polyimide and polyethylene terephthalate are highly heat resistant, firm, and dimensionally stable, and therefore, when used for a graphite composite film, the resulting graphite composite film is easily removable and is highly resistant to scratches while avoiding a decrease in thermal conductivity.

Note that the second adhesive layer may have any structure at its surface that is in contact with the base, provided that the second adhesive layer has a projection/recess structure at its surface which faces away from the base. That is, the second adhesive layer may or may not have a projection/recess structure at its surface that is in contact with the base.

Further note that the first adhesive layer may have any structures at its surface that is in contact with the base and its surface that is in contact with the graphite film. That is, the first adhesive layer may or may not have a projection/recess structure at its surface that is in contact with the base or that is in contact with the graphite film.

(1-2) Graphite Film

The graphite film for use in an embodiment of the present invention is not limited to a particular kind, provided that it is a graphite film that can be used as a heat dissipating component.

For example, a graphite film obtained by making graphite powder such as natural graphite or artificial graphite into a sheet form or a graphite film obtained by treating a polymeric film with heat may be suitably used.

The graphite film obtained by making graphite powder into a sheet form is produced by compressing graphite powder into a sheet form. For the graphite powder to be shaped into a film form, the powder should be in the form of flakes or scales. The most typical method to produce such graphite powder is a method called an expansion method (method for producing expanded graphite). This method involves soaking graphite in an acid such as sulfuric acid to prepare a graphite intercalation compound and then treating the compound with heat to expand, thereby causing delamination of the graphite layers. After the delamination, the graphite powder is washed and thereby the acid is removed, such that a thin film of graphite powder is obtained. The graphite powder, which is obtained by such a method, is further shaped with the use of rolling mill rolls to obtain a film-shaped graphite. A graphite film prepared from expanded graphite produced by such a method has good plasticity and is highly thermally conductive in in-plane directions of the film, and therefore can be suitably used for the purposes of an embodiment of the present invention.

The graphite film obtained by treating a polymeric film with heat is produced by treating, with heat, at least one polymeric film selected from polyimide, polyamide, polyoxadiazole, polybenzothiazole, polybenzobisthiazole, polybenzoxazole, polybenzobisoxasole, polyparaphenylene vinylene, polybenzimidazole, polybenzobisimidazole, and polythiazole.

Of those listed above, a polyimide film is more preferable as a raw film for the graphite film for use in an embodiment of the present invention. The reasons why a polyimide film is more preferred are that the film is readily carbonized and graphitized and therefore is likely to have a high thermal diffusivity, a high thermal conductivity, and a high electrical conductivity in a uniform manner at low temperature and the thermal diffusivity, the thermal conductivity and the electrical conductivity themselves are also likely to become high, that the resulting graphite is highly thermally conductive even when it is thick, and that the resulting graphite film is likely to have excellent crystallinity, high heat resistance and excellent bendability and, when the film is bonded to a protective film, no or little graphite falls off the surface of the graphite film.

A graphite film is obtained from a polymeric film in the following manner. First, the polymeric film, which is a starting material, is preheated to carbonize, and thereafter the carbonized film thus obtained is graphitized at high temperature. The carbonization is performed more preferably under reduced pressure or in an inert gas. The carbonization is performed usually at about 1000° C. For example, in a case where the temperature is raised at a rate of 10° C./min., the temperature is preferably maintained in the region around 1000° C. for about 30 minutes. The graphitization is performed more preferably under reduced pressure or in an inert gas. In the graphitization process, the heat treatment temperature is necessarily 2000° C. or above, and eventually 2400° C. or above, more preferably 2600° C. or above, even more preferably 2800° C. or above. Heat treatment at such temperature provides highly thermally conductive graphite. Higher heat treatment temperatures enable conversion into graphite of better quality. However, from the viewpoint of economy, the conversion into graphite of good quality is preferably achieved at as low a temperature as possible. For super-high temperature 2500° C. or above to be obtained, heating is usually performed by passing current directly through a graphite heater and utilizing the Joule heat generated.

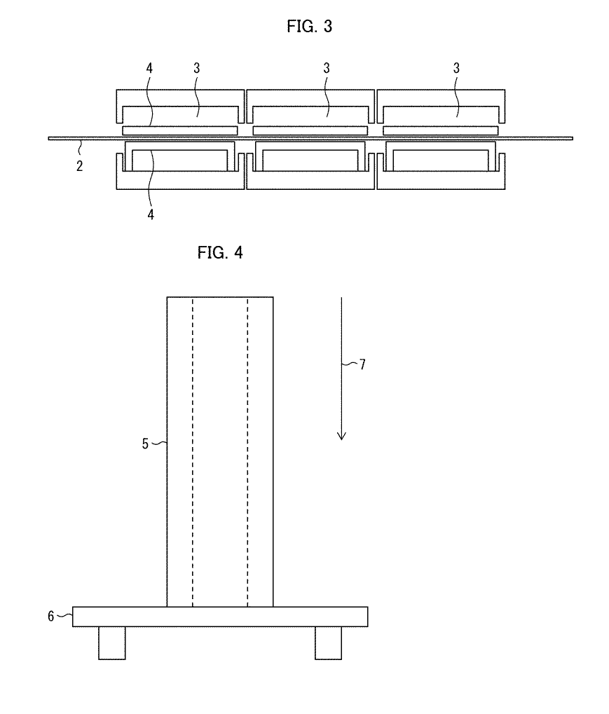

Alternatively, the carbonization may be performed through a sequential carbonization process which uses a heat treatment apparatus that includes two or more heating chambers of 500° C. or above and 900° C. or below. The method using the sequential carbonization process is such that, for example, as shown in FIG. 2, the temperatures inside heating chambers 3 are adjusted to 500° C. or above and 900° C. or below in a manner such that the temperature changes in steps from chamber to chamber and that each heating chamber 3 is uniform in temperature. A polymeric film 2 is put on a winder to be continuously supplied to a heat treatment apparatus 1. It is preferable here that the to-be-heated film be carried at a line speed of 100 cm/min. or higher and 1000 cm/min. or lower with tension having a tensile strength of 5 kgf/cm² or greater and 500 kgf/cm² or less. In each heating chamber 3, it is preferable that the film 2 be sandwiched between graphite jigs 4 from above and below as shown in FIG. 3 and be smoothly passed between the jigs 4. It is preferable here that the pressure that the film 2 experiences in the thickness direction be controlled to 0.5 g/cm² or greater and 10 g/cm² or less. After that, a carbonized film 5 wound in a roll form is placed in a graphitization furnace 6 as shown in FIG. 4 to graphitize. Note that the dashed lines in FIG. 4 indicate where the core of the roll is to be placed. It is preferable here that the TD of the carbonized film be parallel to the direction of gravitational force 7.

The graphite film for use in an embodiment of the present invention has a thermal conductivity of preferably 200 W/mK or greater in in-plane directions of the film and preferably 20 W/mK or less in perpendicular to the in-plane directions of the film. When the graphite film has a thermal conductivity of 200 W/m·K or greater in the in-plane directions of the film, the graphite composite film, which is a composite of the graphite film with an adhesive layer and/or a protection film attached thereto, also has high thermal conductivity. Meanwhile, for heat from the heat generating component to be quickly transferred, the thermal conductivity in the thickness direction of the graphite film should be sufficiently low. When the thermal conductivity in perpendicular to the in-plane directions of the film is 20 W/mK or less, the heat from a heat generating portion of the adherend travels more easily in the in-plane directions, such that heat spots are prevented or reduced.

Furthermore, in the case where the graphite film for use in an embodiment of the present invention is a graphite film obtained by treating a polymeric film with heat, the thermal conductivity of the graphite film is preferably 800 W/m·K or greater in the in-plane directions of the film.

In a case where the graphite film for use in an embodiment of the present invention is a single-layer sheet obtained by making graphite powder into a sheet form or by treating a polymeric film with heat as described earlier, the graphite film has a thickness of preferably 5 μm or greater and 250 μm or less, more preferably 5 μm or greater and 120 μm or less, even more preferably 7 μm or greater and 50 μm or less, particularly preferably 10 μm or greater and 40 μm or less. The graphite film having a thickness of 5 μm or greater is preferred, because such a graphite film has the ability to dissipate heat required for cooling electronic devices. The graphite film having a thickness of 250 μm or less is preferred, because such a graphite film can be built into thin electronic devices.

The graphite film for use in an embodiment of the present invention may be constituted by a single-layer sheet obtained by making graphite powder into a sheet form or by treating a polymeric film with heat. However, in an embodiment of the present invention, the term “graphite film” also includes a graphite laminate in which graphite sheets and bonding layers are alternately stacked. Such bonding layers are, for example, but are not limited to, layers that contain at least one of thermoplastic resins and thermosetting resins. The thickness of each bonding layer is, but not limited to, preferably 0.1 μm or greater and less than 15 μm. The number of the graphite sheets in the graphite laminate is, for example, but is not limited to, 3 or more, more preferably 5 or more, even more preferably or more, particularly preferably 15 or more, most preferably 20 or more. The upper limit of the number of the graphite sheets is, for example, but is not limited to, 1000 or less, more preferably 500 or less, even more preferably 200 or less, still more preferably 100 or less, particularly preferably 80 or less, most preferably 50 or less. A stack of three or more graphite sheets is preferred, because this provides a graphite laminate that has a high heat transport ability and an excellent mechanical strength.

The number of the bonding layers in the graphite laminate is not particularly limited, and may be selected appropriately according to the number of the graphite sheets. For example, the graphite laminate may be such that (i) adjacent graphite sheets essentially have one bonding layer therebetween, or may have two or more bonding layers therebetween, (ii) the graphite laminate may have a graphite sheet only as its top layer or only as its bottom layer, or may have graphite sheets as its top and bottom layers respectively, and/or (iii) the graphite laminate may have a bonding layer only as its top layer or only as its bottom layer, or may have bonding layers as its top and bottom layers respectively. In the present specification, the phrase “graphite sheets and bonding layers are alternately stacked” includes both (a) a case in which adjacent graphite sheets have one bonding layer therebetween and (b) a case in which adjacent graphite sheets have two or more bonding layers therebetween. That is, the bonding layer may be composed of a stack of bonding layers.

The graphite laminate can be produced by a method by which graphite sheets and bonding layers are alternately stacked and the stack is heated and pressed. Alternatively, the graphite laminate can be produced by, for example, a method by which a bonding layer is formed on at least one surface of a graphite sheet to obtain a graphite adhesive sheet and thereafter such graphite adhesive sheets are stacked together.

The graphite laminate may be a laminate obtained by further compressing the alternate stack of the graphite sheets and the bonding layers. As used herein, the term “laminate obtained by compressing” denotes a laminate that has a thinner total thickness of materials than before being compressed. The term “laminate obtained by compressing” also includes a laminate in which constituents of the bonding layer have infiltrated a surface of the graphite sheet. Whether or not the graphite laminate is a laminate obtained through compression can be checked by, for example, i) performing a comparison of thickness of the graphite laminate between before and after the compression or ii) observing interfaces between layers of the graphite laminate under a scanning electron microscope (SEM). It is noted that some other structure(s) may or may not be provided between a graphite sheet and a bonding layer.

In the case where the graphite film for use in an embodiment of the present invention is a graphite laminate like that described above, the thickness of the graphite film, or the graphite laminate, is, but not limited to, preferably 0.05 mm or greater, more preferably 0.09 mm or greater, even more preferably 0.10 mm or greater. The graphite laminate having a thickness of 0.05 mm or greater can transport a larger quantity of heat and thus can be used in electronic devices that generate much heat. The upper limit of the thickness of the graphite film, or the graphite laminate, is, but not limited to, preferably 10 mm or less, more preferably 7.5 mm or less, even more preferably 5 mm or less, particularly preferably 2.5 mm or less, most preferably 1 mm or less, from the viewpoint of obtaining thinner electronic devices.

Each graphite sheet that constitutes the graphite laminate can be produced by a method by which graphite powder such as natural graphite or artificial graphite is made into a sheet form or a method by which a polymeric film is treated with heat, which are described earlier.

The thickness of each graphite sheet that constitutes the graphite laminate is, but not limited to, preferably 10 μm or greater and 200 μm or less, more preferably 12 μm or greater and 150 μm or less, even more preferably 15 μm or greater and 100 μm or less, particularly preferably 20 μm or greater and 80 μm or less. When each graphite sheet has a thickness of 10 μm or greater, the graphite laminate needs fewer graphite sheets, and the poorly thermally conductive bonding layers can be reduced in number. When each graphite sheet has a thickness of 200 μm or less, a highly thermally conductive graphite laminate can be achieved.

The bonding layer may be made of a material in the form of a film or varnish.

Examples of the thermosetting resin include polyurethane (PU), phenol resin, urea resin, melamine-based resin, guanamine resin, vinylester resin, unsaturated polyester, Oligoester acrylate, diallyl phthalate, DKF resin (kind of resorcinol-based resin), xylene resin, epoxy resin, furan resin, polyimide (PI)-based resin, polyetherimide (PEI) resin, polyamide imide (PAI) resin, and polyphenylene ether (PPE). Among these examples, epoxy resin, urethane resin, and polyphenylene ether (PPE) are preferable because they offer wide varieties of material options and have excellent adhesiveness with respect to a graphite sheet.

Examples of the thermoplastic resin include acrylic resin, ionomer, isobutylene maleic anhydride copolymer, acrylonitrile-acryl-styrene copolymer (AAS), acrylonitrile-ethylene-styrene copolymer (AES), acrylonitrile-styrene copolymer (AS), acrylonitrile-butadiene-styrene copolymer (ABS), acrylonitrile-chlorinated polyethylene-styrene copolymer (ACS), methyl methacrylate-butadiene-styrene copolymer (MBS), ethylene-vinyl chloride copolymer, ethylene-vinyl acetate copolymer (EVA), ethylene-vinyl acetate copolymer (EVA)-based resin, ethylene vinyl alcohol copolymer (EVOH), polyvinyl acetate, chlorinated vinyl chloride, chlorinated polyethylene, chlorinated polypropylene, carboxy vinyl polymer, ketone resin, norbornene resin, vinyl propionate, polyethylene (PE), polypropylene (PP), polymethylpentene (TPX), polybutadiene, polystyrene (PS), styrene-maleic anhydride copolymer, methacrylic resin, ethylene-methacrylic acid copolymer (EMAA), polymethylmethacrylate (PMMA), polyvinyl chloride (PVC), polyvinylidene chloride, polyvinyl alcohol (PVA), polyvinyl ether, polyvinyl butyral, polyvinyl formal, cellulose-based resin, nylon 6, nylon 6 copolymer, nylon 66, nylon 610, nylon 612, nylon 11, nylon 12, copolymer nylon, nylon MXD, nylon 46, methoxymethylated nylon, aramid, polyethylene terephthalate (PET), polybutylene terephthalate (PBT), polycarbonate (PC), polyacetal (POM), polyethylene oxide, polyphenylene ether (PPE), modified polyphenylene ether (PPE), polyether ether ketone (PEEK), polyether sulfone (PES), polysulfone (PSO), polyamine sulfone, polyphenylene sulfide (PPS), polyalylate (PAR), poly-para-vinyl phenol, poly-para-methylene styrene, polyallylamine, aromatic polyester, liquid crystal polymer, polytetrafluoroethylene (PTFE), tetrafluoroethylene-ethylene copolymer (ETFE), tetrafluoroethylene-hexafluoropropylene copolymer (FEP), tetrafluoroethylene-hexafluoro propylene-perfluoroalkyl vinyl ether copolymer (EPE), tetrafluoroethylene-perfluoroalkyl vinyl ether copolymer (PFA), polychlorotrifluoroethylene copolymer (PCTFE), ethylene-chlorotrifluoroethylene copolymer (ECTFE), polyvinylidene fluoride (PVDF)-based resin, polyvinyl fluoride (PVF), polyethylene naphthalate (PEN), and polyester-based resin.

The bonding layer is preferably made of an aromatic material (for example, polyester adhesive and polyethylene terephthalate). With this arrangement, stacking graphite sheets and bonding layers on top of each other allows the bonding layers to be substantially parallel to the surfaces of the graphite sheets and prevents the graphite sheets from being easily disrupted, thereby making it possible to produce a graphite laminate having a thermal conductivity close to the theoretical value.

The graphite film for use in an embodiment of the present invention has a volume of more preferably 50 mm³ or greater. When a graphite film has a volume of 50 mm³ or greater, it is difficult to solve the following issue: the graphite film becomes more resilient and decreases in ability to stick to the adherend to which it is bonded; and thus the graphite film and the adherend trap bubbles between them more readily. Especially in a case of a graphite film constituted by a graphite laminate having two or more graphite sheets, it is important to solve the above issue. In this regard, it was found that an adhesive layer of an embodiment of the present invention solves this issue even in the case where the graphite film has a volume of 50 mm³ or greater. Especially in a case where a graphite laminate having two or more graphite sheets is used as a graphite film, the adhesive layer of an embodiment of the present invention is particularly effective because the volume of the graphite laminate tends to be large.

(1-3) Other Layers

The graphite composite film of an embodiment of the present invention only needs to include the graphite film and the adhesive layer, but may further include a separator, a protective layer, an application layer, and/or the like.

(1-3-1) Separator

A separator is a sheet constituted by a base film and a mold release attached to the base film. The separator is disposed on an adhesive face of the adhesive layer. The separator is usually intended to keep the adhesive face of the adhesive layer covered until use of the graphite composite film, and is removed before use of the graphite composite film. In an embodiment of the present invention, the separator may also serve as a template for forming an imprint of a projection/recess structure in the adhesive layer in the production process of the graphite composite film. Such a separator, which serves as a template, is removed after the imprinting operation and another flat separator is attached. Alternatively, the separator serving as a template may remain unremoved and keep the adhesive face covered until use of the graphite composite film.

The separator is not particularly limited as to its thickness, but has a thickness of preferably 2 μm or greater and 200 μm or less, more preferably 6 μm or greater and 100 μm or less, even more preferably 10 μm or greater and 80 μm or less. The separator having a thickness of 200 μm or less does not cause damage to the graphite film when the separator is removed. On the other hand, the separator having a thickness of 2 μm or greater is easy enough to handle.

The material for the base film is not limited to a particular kind. Examples of the material for the base film include PET films, polypropylene films, polyethylene films, polystyrene films, and polyimide films. The mold release is not limited to a particular kind as well. Examples of the mold release include silicone-based mold releases and fluorine-containing mold releases.

(1-3-2) Protective Layer

The protective layer is disposed on the surface of the graphite film which faces away from the adhesive layer. The protective layer is used in order to, for example, protect the graphite film, impart electric insulation, reduce powdering of graphite, and/or reinforce the graphite film.

The protective layer is not particularly limited as to its thickness, but preferably has a thickness of 2 μm or greater and 200 μm or less, more preferably 6 μm or greater and 100 μm or less, particularly preferably 10 μm or greater and 30 μm or less. The protective layer having a thickness of 200 μm or less does not deteriorate the heat dissipation characteristics of the graphite film. On the other hand, the protective layer having a thickness of 2 μm or greater sufficiently functions as a protective layer.

The material for the protective layer is not limited to a particular kind. Examples of the material for the protective layer include polymeric films such as PET films, polypropylene films, polyethylene films, polystyrene films, and polyimide films.

(1-3-3) Application Layer

The application layer is a sheet in which a slightly adhesive material is disposed on a base film to an extent that allows removal of the sheet. The application layer is, for example, disposed on the surface of the protective layer which faces away from the graphite film and is removed before use of the graphite composite film.

(1-4) Graphite Composite Film

In regard to the graphite composite film of an embodiment of the present invention, the peel strength of the graphite composite film on SUS is preferably 4.0 N/25 mm or greater and 12.0 N/25 mm or less, more preferably 5.0 N/25 mm or greater and 8.0 N/25 mm or less, even more preferably 6.0 N/25 mm or greater and 7.0 N/25 mm or less. It is noted here that the peel strength means a value obtained by measurement in accordance with the method described in Examples. The peel strength between the graphite composite film and SUS is preferably 4.0 N/25 mm or greater, because such a graphite composite film firmly adheres to the adherend, and heat diffused within the graphite film is readily transferred to the adherend. The peel strength of 12.0 N/25 mm or less is preferred, because less air is trapped between the adherend and the graphite composite film when the graphite composite film is bonded to the adherend.

The graphite composite film of an embodiment of the present invention preferably has an area of 3 cm² or greater. The graphite composite film having an area of 3 cm² or greater well dissipates heat and thus is suitable for cooling of recent high-power electronic devices. The graphite composite film of an embodiment of the present invention more preferably has an area of 5 cm² or greater, even more preferably has an area of 10 cm² or greater. Meanwhile, existing films have an issue in that, when a large-area film is bonded to a heat generating component, air is trapped between the adherend and the graphite composite film, and the air forms bubbles. In this regard, according to an embodiment of the present invention, it is possible to reduce bubble entrapment even when the area is as large as 25 cm² or greater. Embodiments of the present invention are thus advantageous especially when a graphite composite film has an area as large as 25 cm² or greater.

[2] Method for Producing Graphite Composite Film

A method for producing a graphite composite film in accordance with an embodiment of the present invention is not particularly limited, provided that the earlier-described graphite composite film of an embodiment of the present invention can be produced by the method. The method may be roughly categorized into, for example: a method by which an adhesive layer having a projection/recess structure thereon and a graphite film are stacked together (Production method 1); a method by which an adhesive layer is formed on a graphite film that has a projection/recess structure at its surface and thereby the projection/recess structure of the graphite film is caused to appear at a surface of the adhesive layer (Production method 2); and the like.

(2-1) Production Method 1

The method for producing a graphite composite film of the present embodiment includes a step of stacking an adhesive layer that has a projection/recess structure at at least one surface thereof and a graphite film together in a manner such that the at least one surface having the projection/recess structure faces away from the graphite film.

Specifically, in the present embodiment, an adhesive layer that has a projection/recess structure at at least one surface thereof is prepared in advance, and the adhesive layer and a graphite film are stacked together in a manner such that the at least one surface having the projection/recess structure faces away from the graphite film. The adhesive layer and the graphite film may be stacked together by any method. For example, a laminator may be used to stack the adhesive layer and the graphite film together.

The adhesive layer, the projection/recess structure, and the graphite film have already been described in the section [1] and therefore their descriptions are omitted here.

A method of preparing the adhesive layer that has a projection/recess structure at at least one surface thereof is not particularly limited. For example, the adhesive layer that has a projection/recess structure at at least one surface thereof may be produced by any of the following methods.

(2-1-1) Production Method 1-1

The adhesive layer that has a projection/recess structure at at least one surface thereof may be prepared by a method by which an adhesive solution is applied (or applied by printing) in a manner such that the adhesive solution forms an intended projection/recess structure. The adhesive solution may be applied (or applied by printing) so as to form an intended projection/recess structure by a known method selected as appropriate, and the method is not limited to a particular kind.

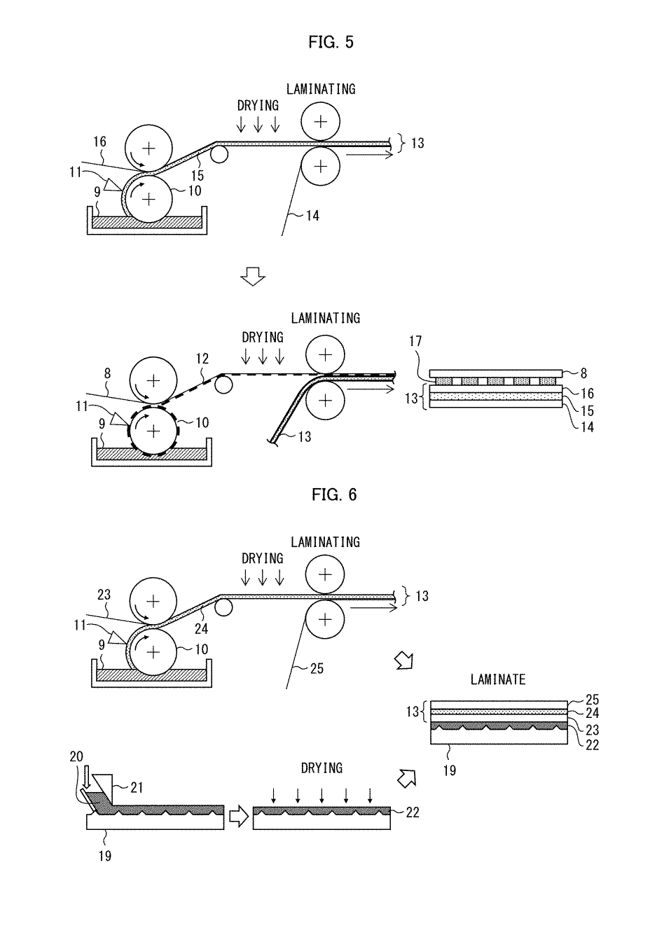

For example, the earlier-described adhesive layer that includes a first adhesive layer, a base, and a second adhesive layer may be prepared by, for example, a method illustrated in FIG. 5. With the use of a gravure coater provided with a squeegee 11, an adhesive solution is applied on a base 16 to form a film (first adhesive layer 15) and is dried, and then a separator 14 is bonded to the first adhesive layer, such that a stack 13 is prepared. Separately, with the use of a gravure coater provided with a squeegee 11, the adhesive solution 9 is applied on a separator 8 by dot printing so that intended island-like projections 17 are formed. A stack 12 thus obtained by dot printing is dried, and then the stack 12 and the earlier-prepared stack 13 are laminated in a manner such that the dot-printed surface (second adhesive layer 17) makes contact with the base 16 of the stack 13. This results in an adhesive layer in which the first adhesive layer 15 (obtained by applying the adhesive solution on the base 16 to form a film and drying the film), the base 16, and the second adhesive layer 17 (obtained by applying the adhesive solution by dot printing and drying the adhesive solution) are stacked in this order.

Also in a case where the adhesive layer is not composed of three layers including a first adhesive layer, a base, and a second adhesive layer but is composed of, for example, a single layer, an intended projection/recess structure may be formed at at least one surface of the adhesive layer by a method by which an adhesive solution is applied (or applied by printing) in a similar manner.

That is, the method for producing a graphite composite film in accordance with the present embodiment may further include a step of preparing an adhesive layer that has a projection/recess structure at at least one surface thereof by applying an adhesive solution (or applying an adhesive solution by printing) in a manner such that the adhesive solution forms an intended projection/recess structure.

Specifically, the method for producing a graphite composite film in accordance with the present embodiment may include: a step of preparing an adhesive layer that has a projection/recess structure at at least one surface thereof by applying an adhesive solution (or applying an adhesive solution by printing) so that the adhesive solution forms an intended projection/recess structure; and a step of stacking the adhesive layer that has the projection/recess structure at the at least one surface thereof and the graphite film together in a manner such that the at least one surface having the projection/recess structure faces away from the graphite film.

(2-1-2) Production Method 1-2

Alternatively, the adhesive layer that has a projection/recess structure at at least one surface thereof may be prepared by a method by which a projection/recess structure, which is complementary to an intended projection/recess structure, of a separator is used to form an imprint in a surface of the adhesive layer. This method makes it possible to easily form a projection/recess structure at a surface of the adhesive layer on the graphite film.

Therefore, the method for producing a graphite composite film in accordance with the present embodiment may further include a step of preparing an adhesive layer that has a projection/recess structure at at least one surface thereof by forming an imprint of a projection/recess structure of a surface of a separator in the at least one surface of the adhesive layer.

Specifically, the method for producing a graphite composite film in accordance with the present embodiment may include: a step of preparing an adhesive layer that has a projection/recess structure at at least one surface thereof by forming an imprint of a projection/recess structure of a surface of a separator in the at least one surface of the adhesive layer; and a step of stacking the adhesive layer that has the projection/recess structure at the at least one surface thereof and the graphite film together in a manner such that the at least one surface having the projection/recess structure faces away from the graphite film.

An imprint of a projection/recess structure of a surface of a separator may be formed in a surface of the adhesive layer by a known method selected as appropriate, and the method is not particularly limited. For example, the method may be: a method by which an adhesive solution is applied on a surface, which has a projection/recess structure, of a separator to form a film and thereby an imprint of the projection/recess structure is formed (Imprint method 1); or a method by which a surface, which has a projection/recess structure, of a separator is brought into contact with the adhesive layer and thereby an imprint of the projection/recess structure is formed in the adhesive layer (Imprint method 2).

In the present embodiment, the surface, which has a projection/recess structure, of the separator preferably has a surface roughness that is 0.06 μm or greater and 1.00 μm or less in Ra and that is 0.3 μm or greater and 10.0 μm or less in Rz, more preferably has a surface roughness that is 0.30 μm or greater and 0.70 μm or less in Ra and that is 2.90 μm or greater and 5.10 μm or less in Rz. It is preferable that the surface, which has a projection/recess structure, of the separator have a surface roughness falling within the above ranges, because this more suitably reduces bubble entrapment between the adherend and the graphite composite film when the graphite composite film is bonded to the adherend without impairing the heat dissipation ability of the graphite composite film.

(Imprint Method 1)

The method by which an adhesive solution is applied on a surface, which has a projection/recess structure, of a separator to form a film and thereby an imprint of the projection/recess structure is formed is not particularly limited and may be any known method selected as appropriate.

For example, the earlier-described adhesive layer that includes a first adhesive layer, a base, and a second adhesive layer may be prepared by, for example, a method illustrated in FIG. 6. With the use of a gravure coater provided with a squeegee 11, an adhesive solution is applied on a base 23 to form a film (first adhesive layer 24) and is dried, and then a separator 25 is bonded to the first adhesive layer, such that a stack 13 is prepared. Next, the adhesive solution 20 is applied on a separator 19, which has been embossed to have a projection/recess structure complementary to an intended projection/recess structure, with the use of a squeegee 21 to form a film having an intended thickness. The liquid film on the separator 19 is dried to give a second adhesive layer 22. The stack thus obtained and the earlier-prepared stack 13 are laminated in a manner such that the surface of the second adhesive layer 22 opposite the separator 19 makes contact with the base 23 of the stack 13. This results in an adhesive layer in which the first adhesive layer 24 (obtained by applying the adhesive solution on the base 23 to form a film and drying the film), the base 23, and the second adhesive layer 22 (in which an imprint of the projection/recess structure of the separator was formed by applying the adhesive solution on the separator 19 to form a film and drying the film) are stacked in this order. It is noted that, after the imprint of the projection/recess structure is formed, the separator 19 may be removed and another flat separator may be attached to the second adhesive layer 22 to keep the adhesive face of the second adhesive layer 22 covered until use of the graphite composite film. Also in a case where the adhesive layer is not composed of three layers including a first adhesive layer, a base, and a second adhesive layer but is composed of, for example, a single layer, an imprint may be formed similarly by a method by which an adhesive solution is applied on a separator embossed to have a projection/recess structure complementary to an intended projection/recess structure to form a film and thereby the imprint of the projection/recess structure is formed.

(Imprint Method 2)

The following describes the method by which a surface, which has a projection/recess structure, of a separator is brought into contact with the adhesive layer and thereby an imprint of the projection/recess structure is formed. It is noted here that the adhesive layer, which makes contact with the separator, is a dried adhesive layer, and that the dried adhesive layer means an adhesive layer which contains 5% by weight or less of a solvent remaining therein. The percentage of the remaining solvent can be calculated using the following equation after thoroughly drying an adhesive alone at a temperature equal to or above the boiling point of the solvent in an oven or the like and measuring the weight of the adhesive alone before and after the drying.

Percentage of remaining solvent (%)=(weight before drying−weight after drying)/weight before drying×100

The method by which a surface, which has a projection/recess structure, of a separator is brought into contact with the adhesive layer and thereby an imprint of the projection/recess structure is formed is not particularly limited and may be any known method selected as appropriate. The method may be, for example, a method by which a separator having a projection/recess structure at its surface and an adhesive layer are laminated together. This method makes it possible to prepare an adhesive layer that has a projection/recess structure at at least one surface thereof by utilizing existing equipment or products, simply by changing the design of the separator.

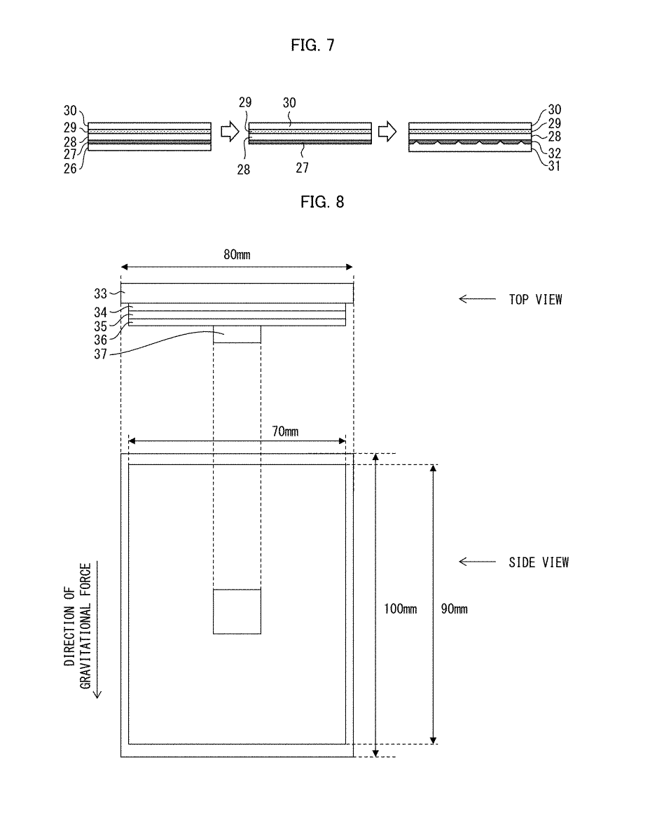

For example, the earlier-described adhesive layer that includes a first adhesive layer, a base, and a second adhesive layer may be prepared by, for example, a method illustrated in FIG. 7. As illustrated in FIG. 7, one separator 26 is removed from an adhesive layer composed of three layers including a first adhesive layer 29, a base 28 and an adhesive layer 27 that has no projection/recess structures thereon, and the adhesive layer and a separator 31 embossed to have a projection/recess structure complementary to an intended projection/recess structure are laminated in a manner such that the embossed surface makes contact with the exposed adhesive layer 27 that has no projection/recess structures thereon, so that an adhesive layer is obtained. This results in an adhesive layer in which the first adhesive layer 29 (in contact with the other separator 30 which remains unremoved), the base 28, and the second adhesive layer 32 (having an imprint of the projection/recess structure of the embossed separator formed therein by the lamination) are stacked together in this order. It is noted that, after the imprint of the projection/recess structure is formed, the separator 31 may be removed and another flat separator may be attached to the second adhesive layer 32 to keep the adhesive face of the second adhesive layer 32 covered until use of the graphite composite film. Also in a case where the adhesive layer is not composed of three layers including a first adhesive layer, a base, and a second adhesive layer but is composed of, for example, a single layer, the imprint may be formed in a similar manner.

(2-2) Production Method 2

The method for producing a graphite composite film in accordance with the present embodiment involves forming a projection/recess structure at a surface of an adhesive layer by forming the adhesive layer on a graphite film that has a projection/recess structure at its surface and causing the projection/recess structure of the graphite film to appear at the surface of the adhesive layer.

The present embodiment only needs to use a graphite film having a projection/recess structure at its surface and form an adhesive layer on this graphite film. Therefore, it is possible to easily form a projection/recess structure at a surface of the adhesive layer of the graphite composite film. A method of forming the adhesive layer on the graphite film having a projection/recess structure at its surface is not particularly limited and may be any method. The method is, for example: a method by which an adhesive layer is formed on a graphite film with the use of a laminator; a method by which an adhesive solution is applied on a graphite film to form a film and the film is dried; or the like.

The adhesive layer, the projection/recess structure, and the graphite film have already been described in the section [1] and therefore their descriptions are omitted here.

A method of producing a graphite film having a projection/recess structure at its surface is not particularly limited, and is, for example: a method by which, in the production process of a graphite film, the graphite film is extended with the use of a rolling mill roll having an embossed surface; a method by which, in producing a graphite film by treating a polymeric film with heat, the graphitization is performed by raising temperature rapidly; a method by which, in producing a graphite film by treating a polymeric film with heat, an alternate stack of polymeric films and natural graphite sheets is carbonized and graphitized; or the like. In a case where the graphite film is the earlier-described graphite laminate, the graphite laminate may be produced by, for example, a method by which a graphite sheet having a projection/recess structure at its surface, which was produced by the earlier-described method, is used as the bottom layer or the top layer of the laminate so that the laminate has the projection/recess structure at its surface.

The surface, which has a projection/recess structure, of the graphite film preferably has a surface roughness that is 0.55 μm or greater and 1.70 μm or less in Ra and that is 2.3 μm greater and 6.00 μm or less in Rz, more preferably has a surface roughness that is 0.80 μm or greater and 1.30 μm or less in Ra and that is 3.20 μm or greater and 4.70 μm or less in Rz. An arrangement in which the surface, which has a projection/recess structure, of the graphite film has a surface roughness falling within the above ranges is preferred, because this makes it easy to form a projection/recess structure even on a normal adhesive layer which has no projection/recess structure at its surface.

In a case where the graphite film for use in an embodiment of the present invention is a single-layer sheet described earlier, the graphite film, which has a projection/recess structure at its surface, has a thickness of preferably 5 μm or greater and 250 μm or less, more preferably 5 μm or greater and 120 μm or less, even more preferably 7 μm or greater and 50 μm or less, particularly preferably 10 μm or greater and 40 μm or less. The graphite film having a thickness within the above range is preferred, because this makes it easy to form a projection/recess structure on the adhesive layer.

In a case where the graphite film for use in an embodiment of the present invention is a graphite laminate described earlier, the thickness of the graphite film, or the graphite laminate, is, but not limited to, preferably 0.05 mm or greater, more preferably 0.09 mm or greater, even more preferably 0.10 mm or greater. The upper limit of the thickness of the graphite film, or the graphite laminate, is, but not limited to, preferably 10 mm or less, more preferably 7.5 mm or less, even more preferably 5 mm or less, particularly preferably 2.5 mm or less, most preferably 1 mm or less, from the viewpoint of obtaining thinner electronic devices.

The surface of the adhesive layer at which a projection/recess structure has been formed by the above-described method preferably has a surface roughness that is 0.19 μm or greater and 10 μm or less in Ra and that is 1.6 μm or greater and 100 μm or less in Rz, more preferably has a surface roughness that is 0.19 μm or greater and 0.80 μm or less in Ra and that is 2.0 μm or greater and 5.00 μm or less in Rz, even more preferably has a surface roughness that is 0.25 μm or greater and 0.60 μm or less in Ra and that is 2.5 μm or greater and 4.00 μm or less in Rz. Alternatively, the surface roughness in Ra is preferably 0.19 μm or greater and 10 μm or less, more preferably 0.19 μm or greater and 0.80 μm or less, even more preferably 0.25 μm or greater and 0.60 μm or less. Alternatively, the surface roughness in Rz is preferably 1.6 μm or greater and 100 μm or less, more preferably 2.0 μm or greater and 5.00 μm or less, even more preferably 2.5 μm or greater and 4.00 μm or less. It is preferable that the adhesive layer have a surface roughness falling within the above range, because this reduces bubble entrapment between the adherend and the graphite composite film when the graphite composite film is bonded to the adherend without impairing the heat dissipation ability of the graphite composite film.

The adhesive layer, which has a projection/recess structure formed at its surface by the above-described method, has a thickness of preferably 1.00 μm or greater and 20.00 μm or less, more preferably 2.00 μm or greater and 10.00 μm or less, even more preferably 3.00 μm or greater and 7.00 μm or less. The adhesive layer having a thickness of 1.00 μm or greater is preferred, because such an adhesive layer ensures connection with the adherend. The adhesive layer having a thickness of 20.00 μm or less is preferred, because the projection/recess structure on the graphite film readily appears at a surface of the adhesive.

The methods for producing a graphite composite film (Production methods 1 and 2) described above may further include, in addition to the above steps, a step of attaching a protective layer and/or a step of attaching an application layer.

[3] Heat Dissipating Component

The graphite composite film in accordance with an embodiment of the present invention can reduce bubble entrapment between itself and an adherend when bonded to the adherend without impairing its heat dissipation ability. Therefore, the graphite composite film can be suitably used in heat dissipating components. For this reason, the present invention also encompasses a heat dissipating component that includes a graphite composite film in accordance with an embodiment of the present invention.

Specifically, a heat dissipating component in accordance with an embodiment of the present invention only needs to include a graphite composite film, the graphite composite film including: a graphite film; and an adhesive layer in contact with the graphite film, wherein the area of the graphite film covered with an adhesive is 35% or more and 100% or less of the total area of the graphite film, and the adhesive layer has a projection/recess structure at a surface thereof which faces away from the graphite film. The graphite composite film has already been described in the “[1] Graphite composite film” section and therefore its description is omitted here.

The heat dissipating component in accordance with an embodiment of the present invention is not particularly limited as to its configuration, provided that the heat dissipating component includes a graphite composite film of an embodiment of the present invention. The heat dissipating component is, for example, a heat dissipating component obtained by attaching a graphite composite film of an embodiment of the present invention to an adherend. The adherend is, for example, a heat generator or the like. The heat generator is made of, for example, a metal such as SUS, resin, and/or the like. More specifically, the heat generator is, for example, a housing of a heat generating component.

In a case where the graphite film has a thickness of 90 μm or less, more preferably 60 μm or less, or in a case where the graphite film is constituted by preferably a single-layer graphite sheet, a projection/recess structure appears at the surface of the graphite film opposite the adherend due to the projection/recess structure of the adhesive layer. Furthermore, in a case where a protective layer is disposed on the surface of the graphite film opposite the adhesive layer, i.e., on the surface of the graphite film opposite the adherend, or in a case where a protective layer and an application layer are stacked on the surface of the graphite film opposite the adhesive layer, a projection/recess structure appears at the surface of each of the protective and application layers due to the projection/recess structure of the adhesive layer. The projection/recess structure appearing at the surface of the graphite film or the protective layer is visible to eyes. In this case, the surface of the protective layer having the projection/recess structure thereon has a surface roughness that is preferably 0.15 μm or greater and 10 μm or less, more preferably 0.17 μm or greater and 1.0 μm or less, even more preferably 0.18 μm or greater and 0.25 μm or less in Ra and that is preferably 1.0 μm or greater and 100 μm or less, more preferably 1.0 μm or greater and 10 μm or less, even more preferably 1.50 μm or greater and 2.00 μm or less in Rz. The combination of Ra and Rz is such that: it is preferable that Ra be 0.15 μm or greater and 10 μm or less and Rz be 1.0 μm or greater and 100 μm or less; it is more preferable that Ra be 0.17 μm or greater and 1.0 μm or less and Rz be 1.0 μm or greater and 10 μm or less; it is even more preferable that Ra be 0.18 μm or greater and 0.25 μm or less and Rz be 1.50 μm or greater and 2.00 μm or less.

In a case where the graphite film has a thickness greater than 60 μm, more preferably greater than 90 μm, or in a case where the graphite film is constituted by preferably a graphite laminate, the graphite film is thick and therefore the projection/recess structure at the surface of the graphite film opposite the adherend, which results from the projection/recess structure of the adhesive layer, is not visible to eyes. In this case, by observing a cross section of the adherend with the graphite composite film attached thereto, it is possible to check whether the adhesive layer has a projection/recess structure and whether the area of the graphite film covered with an adhesive is 35% or more and 100% or less of the total area of the graphite film.

The present invention is not limited to the embodiments, but can be altered by a skilled person in the art within the scope of the claims. The present invention also encompasses, in its technical scope, any embodiment derived by combining technical means disclosed in differing embodiments.

The present invention includes the following aspects.

(1) A graphite composite film including: a graphite film; and an adhesive layer in contact with the graphite film, wherein the area of the graphite film covered with an adhesive is 35% or more and 100% or less of the total area of the graphite film, and the adhesive layer has a projection/recess structure at a surface thereof which faces away from the graphite film.
(2) The graphite composite film according to (1), wherein the surface roughness in Ra of the surface of the adhesive layer, the surface having the projection/recess structure, is 0.19 μm or greater and 10 μm or less.
(3) The graphite composite film according to (1) or (2), wherein the surface roughness in Rz of the surface of the adhesive layer, the surface having the projection/recess structure, is 1.6 μm or greater and 100 μm or less.
(4) The graphite composite film according to any of (1) to (3), wherein the adhesive layer has a thickness of 1.00 μm or greater and 20.00 μm or less.
(5) The graphite composite film according to any one of (1) to (4), wherein the projection/recess structure at the surface of the adhesive layer is defined by grooves in a lattice-like pattern or a striped pattern or by separate island-like projections.
(6) The graphite composite film according to (5), wherein the grooves in a lattice-like pattern or a striped pattern have a pitch of 0.05 mm or greater and 2.0 mm or less.
(7) The graphite composite film according to any one of (1) to (6), wherein: the adhesive layer includes a first adhesive layer, a base, and a second adhesive layer; the first adhesive layer, the base, and the second adhesive layer of the adhesive layer are stacked on the graphite film in this order from the graphite film; the area of the graphite film covered with the adhesive in the second adhesive layer is 35% or more and 100% or less of the total area of the graphite film; and the adhesive layer has the projection/recess structure at a surface of the second adhesive layer, the surface facing away from the base.
(8) The graphite composite film according to (7), wherein:

the second adhesive layer is constituted by adhesive parts disposed on the base; and

the projection/recess structure at the surface of the adhesive layer includes projections which are constituted by the adhesive parts and recesses in which there is no adhesive and the base is exposed.

(9) The graphite composite film according to (8), wherein the adhesive parts occupy 35% or more of the total area of the adhesive layer.
(10) The graphite composite film according to (8) or (9), wherein, assuming that the adhesive parts are regularly arranged projections in the form of polygonal, rod-shaped, and/or strip-shaped islands, the distance between the mutually facing edges of adjacent ones of the projections is 0.01 mm or greater.
(11) The graphite composite film according to any one of (1) to (10), wherein a peel strength between the graphite composite film and SUS is 4.0 N/25 mm or greater and 12.0 N/25 mm or less.
(12) The graphite composite film according to any of (1) to (11), which has an area of 3 cm² or greater.
(13) The graphite composite film according to any of (1) to (12), wherein the graphite film has a thickness of 90 μm or greater.
(14) The graphite composite film according to any of (1) to (13), wherein: the graphite film is a graphite laminate including alternately stacked graphite sheets and bonding layers; and the number of the graphite sheets in the graphite laminate is three or more.
(15) The graphite composite film according to any one of (1) to (14), wherein the graphite film has a volume of 50 mm³ or greater.
(16) A method for producing a graphite composite film that includes a graphite film and an adhesive layer in contact with the graphite film, the method including stacking the adhesive layer and the graphite film together in a manner such that: the area of the graphite film covered with an adhesive is 35% or more and 100% or less of the total area of the graphite film; and at least one surface of the adhesive layer, the at least one surface having a projection/recess structure thereon, faces away from the graphite film.
(17) A method for producing a graphite composite film that includes a graphite film and an adhesive layer in contact with the graphite film, the method including: preparing the adhesive layer which has a projection/recess structure at at least one surface thereof by forming an imprint of a projection/recess structure of a surface of a separator in the at least one surface of the adhesive layer; and stacking the adhesive layer and the graphite film together in a manner such that the at least one surface having the projection/recess structure thereon faces away from the graphite film.
(18) The method according to (17), wherein the surface roughness of the surface of the separator, the surface having the projection/recess structure, is 0.06 μm or greater and 1.00 μm or less in Ra and is 0.3 μm or greater and 10.0 μm or less in Rz.
(19) The method according to (17) or (18), wherein the imprint of the projection/recess structure of the surface of the separator is formed by applying an adhesive solution to the surface of the separator to form a film.
(20) The method according to (17) or (18), wherein the imprint of the projection/recess structure of the surface of the separator is formed in the at least one surface of the adhesive layer by bringing the separator into contact with the adhesive layer which contains 5% or less of a solvent remaining therein.
(21) A method for producing a graphite composite film that includes a graphite film and an adhesive layer in contact with the graphite film, the method including:

forming a projection/recess structure at a surface of the adhesive layer by forming the adhesive layer on the graphite film which has a projection/recess structure at a surface thereof to thereby cause the projection/recess structure of the graphite film to appear at the surface of the adhesive layer.

(22) The method according to (21), wherein the surface roughness of the surface of the graphite film, the surface having the projection/recess structure, is 0.55 μm or greater and 1.70 μm or less in Ra and is 2.3 μm or greater and 6.00 μm or less in Rz.
(23) The method according to (21) or (22), wherein the graphite film has a thickness of 5 μm or greater and 120 μm or less.
(24) The method according to any of (21) to (23), wherein the surface roughness of the surface of the adhesive layer, the surface having the projection/recess structure, is 0.8 μm or less in Ra and is 4.5 μm or less in Rz.
(25) A heat dissipating component including a graphite composite film, the graphite composite film including: a graphite film; and an adhesive layer in contact with the graphite film, wherein the area of the graphite film covered with an adhesive is 35% or more and 100% or less of the total area of the graphite film, and the adhesive layer has a projection/recess structure at a surface thereof which faces away from the graphite film.
(26) The heat dissipating component according to (25), further including an adherend bonded to the graphite composite film.
(27) The heat dissipating component according to (26), further including a protective layer disposed on a surface of the graphite composite film, the surface facing away from the adherend, and the protective layer having a surface with a surface roughness that is 0.15 μm or greater and 10 μm or less in Ra and that is 1.0 μm or greater and 100 μm or less in Rz.

### EXAMPLES

The following more specifically describes the present invention on the basis of Examples. Note, however, that the present invention is not limited to these Examples.

It is noted that the thicknesses and surface roughnesses of adhesive layers, graphite films (GS), protective layers, and application layers for use in Examples, and the distance between island-like projections of a projection/recess structure of an adhesive layer, pitch, and the depth and area of grooves of the projection/recess structure of the adhesive layer for use in Examples were measured by the following measurement methods.

<Distance Between Island-Like Projections of Projection/Recess Structure of Adhesive Layer, Pitch, and Depth and Area of Grooves of Projection/Recess Structure>

The distance between island-like projections of a projection/recess structure of a second adhesive layer, pitch, and the depth and area of grooves of the projection/recess structure were measured with the use of a QUICK SCOPE (model number: QS-L1020Z/AF) available from Mitutoyo Corporation. The measurement was performed under the conditions enabling image observation. In regard to PSA1-1 to PSA1-7, their images were observed under the conditions in which the magnification was 0.50× and the illumination was such that co-axial light was 0, stage light was 0, and ring light was 50, and thereby the distance between island-like projections and the area occupied by the projections were measured. In regard to PSA2-1 to PSA2-6, their images were observed under the conditions in which the magnification was 0.50× and the illumination was such that co-axial light was 20, stage light was 0, and ring light was 0, and thereby the pitch and depth of the grooves and the area occupied by the grooves were measured. In regard to other adhesive layers, the measurements were also performed under the conditions enabling image observation.

<Surface Roughnesses of Graphite Film (GS), Separator, and Protective Layer of Graphite Composite Film on Heat Dissipating Component>

A graphite film (GS), a separator, and a protective layer of a graphite composite film on a heat dissipating component were measured for their surface roughness with the use of a surface roughness measuring instrument (model number: SE-3500) (main body model number: DR-200X51) at a room temperature of 23° C. and a humidity of 50% under the following measurement conditions.

The measurement was performed at ten locations on each sample and the mean of the ten measured values was used as Ra or Rz.

Evaluation length: any length

Any length: 0.8 mm

Vertical magnification: ×2000

Horizontal magnification: ×100

Cutoff value: 0.8 mm

Drive speed: 0.5 mm/s

<Surface Roughness of Adhesive Layer>

The adhesive layer was measured for surface roughness in the same manner as the graphite film (GS) and the separator, except that the “Any length” was changed to 8.0 mm.

<Thickness>

Evaluation of thicknesses of an application layer, a protective layer, a graphite film (GS), an adhesive layer, a graphite composite film, and the like was performed by measuring, before lamination, the thickness of each sample at the central portion with the use of a thickness gauge (HEIDENHAIN-CERTO) available from Heidenhain Corporation at a room temperature of 23° C. and a humidity of 50%. In a case of a layer having a projection/recess structure thereon, the maximum thickness of the central portion was measured as the thickness of that layer.

[Production of Graphite Film]

<GS1>

As illustrated in FIG. 2, a polyimide film Apical NPI in the form of a roll having a birefringence of 0.15, a thickness of 62 μm, a width of 250 mm, and a length of 50 m, produced by KANEKA CORPORATION, was put on a winder and was subjected to a sequential carbonization step by continuously feeding the polyimide film to a heat treatment apparatus that includes seven heating chambers. Each heating chamber had a dimension of 50 cm in the MD (machine direction: flow direction) and a dimension of 300 mm in the TD (transverse direction: width direction), and the temperatures inside the heating chambers were adjusted to 550° C., 600° C., 650° C., 700° C., 750° C., 800° C., and 850° C. respectively in this order from the entrance of the film in a manner such that each heating chamber was uniform in temperature. The film was carried at a line speed of 50 cm/min. with tension having a tensile strength of 30 kgf/cm² applied thereto. In each heating chamber, the film was sandwiched between graphite jigs from above and below as shown in FIG. 3 and was smoothly passed between the jigs. The pressure that the film experienced in the thickness direction was controlled at 2 g/cm². Next, a carbonized film wound in a roll form was placed in a graphitization furnace as shown in FIG. 4 in a manner such that the TD of the carbonized film was parallel to the direction of gravitational force, and was treated with heat by heating at a rate of 2° C./min. to 2900° C. The obtained graphitized film was extended with the use of two rolls having a diameter of 300 mm and a width of 300 mm with a pressure of 3 tons applied thereto. In this way, a graphite film 1 (GS1) was obtained.

<GS2>

A graphite film 2 (GS2) was obtained in the same manner as the GS1, except that the rate of heating to 2900° C. was changed to 5° C./min.

<GS3>

A graphite film 3 (GS3) was obtained in the same manner as the GS1, except that the rate of heating to 2900° C. was changed to 3° C./min.

<GS4>

A graphite film 4 (GS4) was obtained in the same manner as the GS1, except that the rate of heating to 2900° C. was changed to 4° C./min.

<GS5>

A graphite film 5 (GS5) was obtained in the same manner as the GS1, except that the rate of heating to 2900° C. was changed to 7.5° C./min.

<GS6>

A graphite film 6 (GS6) was obtained in the same manner as the GS1, except that the rate of heating to 2900° C. was changed to 10° C./min.

<GS7>

A graphite film 7 (GS7) was obtained in the same manner as the GS1, except that the surfaces of the pressure rolls were embossed and had a surface roughness of 1.30 μm in Ra and 5.0 μm in Rz.

<GS8>

A polyimide film Apical AH, having a birefringence of 0.12, a thickness of 62 μm, a width of 250 mm, and a length of 50 m, produced by KANEKA CORPORATION, was cut into a length of 250 mm, and such polyimide films and natural graphite sheets each having a thickness of 200 μm were alternately stacked together so that the total number of layers was 100, and a graphite weight plate was placed on this stack in a manner such that a load of 5 g/cm² was applied to the films. This stack of polyimide films and graphite sheets, with the weight plate placed thereon, was placed in a carbonization furnace and was carbonized with heating at a heating rate of 2° C./min. to 1400° C. Next, the carbonized stack of carbonized films and graphite sheets, with the weight plated placed thereon, was directly put into a graphitization furnace and was graphitized with heating at a heating rate of 5° C./min. to 2900° C. The obtained graphitized film was sandwiched between two polyimide films each having a thickness of 125 μm, and pressed with a pressure of 10 MPa. In this way, a graphite film 8 (GS8) was obtained.

<GS9>

Three graphite sheets each having a thickness of 32 μm and two adhesive films each having a thickness of 5 μm were alternately stacked together to obtain a stack having graphite sheets as the outermost layers. This stack was pressure-bonded under heat to obtain a graphite laminate (thickness: 106 μm) including three graphite sheets. This graphite laminate was used as a graphite film 9 (GS9).

<GS10>

Five graphite sheets each having a thickness of 32 μm and four adhesive films each having a thickness of 5 μm were alternately stacked together to obtain a stack having graphite sheets as the outermost layers. This stack was pressure-bonded under heat to obtain a graphite laminate (thickness: 180 μm) including five graphite sheets. This graphite laminate was used as a graphite film 10 (GS10).

<GS11>

Fifteen graphite sheets each having a thickness of 32 μm and fourteen adhesive films each having a thickness of 5 μm were alternately stacked together to obtain a stack having graphite sheets as the outermost layers. This stack was pressure-bonded under heat to obtain a graphite laminate (thickness: 550 μm) including fifteen graphite sheets. This graphite laminate was used as a graphite film 11 (GS11).

<GS12>

Four graphite sheets each having a thickness of 32 μm and three adhesive films each having a thickness of 5 μm were alternately stacked together to obtain a stack having graphite sheets as the outermost layers. This stack was pressure-bonded under heat to obtain a graphite laminate (thickness: 143 μm) including four graphite sheets. This graphite laminate was used as a graphite film 12 (GS12).

<GS13>

Ten graphite sheets each having a thickness of 32 μm and nine adhesive films each having a thickness of 5 μm were alternately stacked together to obtain a stack having graphite sheets as the outermost layers. This stack was pressure-bonded under heat to obtain a graphite laminate (thickness: 365 μm) including ten graphite sheets. This graphite laminate was used as a graphite film 13 (GS13).

<GS14>

A polyimide film was heated to obtain a graphite sheet having a thickness of 200 μm. This graphite sheet was used as a graphite film 14 (GS14).

[Production of Adhesive Layer]

<PSA1-1>

An adhesive layer was prepared by a method illustrated in FIG. 5. With the use of a gravure coater, an acrylic adhesive solution diluted with toluene was applied on a PET base having a thickness of 2 μm so that the resulting dry film would have a thickness of 2 μm and was dried, and then a PET separator with one surface silicone-treated, having a thickness of 75 μm, was bonded to the film of the acrylic adhesive solution in a manner such that the silicone-treated surface was bonded to the film of the acrylic adhesive solution. In this way, a stack A was prepared. Separately, with the use of a gravure coater, the acrylic adhesive solution was applied on a PET separator with one surface silicone-treated, having a thickness of 75 μm, in a dotted manner by printing (in Table 2, this dotted structure is represented as “Island-like projections” in “Structure” of “Second adhesive layer”) on the silicone-treated surface so that: 1.3 mm×1.3 mm square island-like projections would be regularly arranged as illustrated in (b) of FIG. 1 after drying; adjacent square island-like projections would have their edges facing each other at a distance (distance between island-like projections) of 0.19 mm after drying; dried adhesive parts would occupy 76.1% of the total area of the adhesive layer (represented as “adhesive part area” in Table 2 and in the following production of PSA1-2 to PSA1-7); and the dried adhesive would have a thickness of 2 μm. The stack obtained after printing in a dotted manner was dried, and then this stack and the earlier-prepared stack A were laminated in a manner such that the surface with dots made contact with the base of the stack A. In this way, PSA1-1 was obtained. PSA1-1 is an adhesive layer in which the first adhesive layer (which is obtained by applying the acrylic adhesive solution to form a film and drying the film) of the stack A, the base of the stack A, and the second adhesive layer (which is obtained by applying the acrylic adhesive solution in a dotted manner by printing and drying the solution) are stacked in this order. PSA1-1 thus obtained is covered with PET separators on both sides. It is noted that, in this adhesive layer, the separate island-like projections, which constitute a projection/recess structure at a surface of the second adhesive layer, can be regarded as being equal to the grooves in a square lattice-like pattern having a pitch of 1.5 mm, a width of 0.19 mm, and a depth of 2 μm.

<PSA1-2>

PSA1-2 was obtained in the same manner as PSA1-1, except that the gravure roll was adjusted so that island-like projections 1.3 mm on a side would be obtained, the distance between island-like projections would be 0.88 mm, and the adhesive part area would be 35.6%.

<PSA1-3>

PSA1-3 was obtained in the same manner as PSA1-1, except that the gravure roll was adjusted so that island-like projections 1.3 mm on a side would be obtained, the distance between island-like projections would be 0.50 mm, and the adhesive part area would be 52.2%.

<PSA1-4>

PSA1-4 was obtained in the same manner as PSA1-1, except that the gravure roll was adjusted so that island-like projections 2.25 mm on a side would be obtained, the distance between island-like projections would be 0.88 mm, and the adhesive part area would be 85.0%.

<PSA1-5>

PSA1-5 was obtained in the same manner as PSA1-1, except that the gravure roll was adjusted so that island-like projections 3.5 mm on a side would be obtained, the distance between island-like projections would be 0.19 mm, and the adhesive part area would be 90.0%.

<PSA1-6>

PSA1-6 was obtained in the same manner as PSA1-1, except that the gravure roll was adjusted so that island-like projections 0.7 mm on a side would be obtained, the distance between island-like projections would be 0.1 mm, and the adhesive part area would be 76.6%.

<PSA1-7>

PSA1-7 was obtained in the same manner as PSA1-1, except that the gravure roll was adjusted so that island-like projections 0.07 mm on a side would be obtained, the distance between island-like projections would be 0.01 mm, and the adhesive part area would be 76.6%.

<PSA2-1>

An adhesive layer was prepared by a method illustrated in FIG. 6. With the use of a gravure coater, an acrylic adhesive solution diluted with toluene was applied on a PET base having a thickness of 2 μm so that the resulting dry film would have a thickness of 2 μm, and was dried, and then a PET separator with one surface silicone-treated, having a thickness of 75 μm, was bonded to the film of the acrylic adhesive solution in a manner such that the silicone-treated surface was bonded to the film of the acrylic adhesive solution. In this way, a stack A was prepared. Next, the acrylic adhesive solution was applied on a PET separator with one surface embossed and silicone-treated (having a thickness of 75 μm), which had been embossed so that the embossed surface formed linear projections in a 0.2 mm×0.3 mm rectangular lattice-like pattern having an average height of 1.0 μm. (This is represented as “having a pitch of 0.2×0.3 mm and an average peak height of 1.0 μm” in the following production of PSA2-2 to PSA2-5. It is noted that, because of imprinting of the projection/recess structure, Table 2 reads “Pitch is 0.2×0.3 mm, Average depth of grooves is 1.0 μm”.) (In Table 2, this structure is represented as “Grooves in a lattice-like pattern” in “Structure” of “Second adhesive layer”.) The acrylic adhesive solution here was applied so that the dried adhesive would have a thickness of 2 μm. The film of the acrylic adhesive solution was dried, and then this stack and the earlier-prepared stack A were laminated in a manner such that the film of the acrylic adhesive solution made contact with the base of the stack A. In this way, PSA2-1 was obtained. After that, the embossed PET separator was removed and thereby the surface, which had an imprint of the embossed surface therein, of the layer obtained by drying the film of the acrylic adhesive solution was exposed. Another flat PET separator with one surface silicone-treated, having a thickness of 75 μm, was attached in a manner such that the silicone-treated surface made contact with the above exposed surface. PSA2-1 is an adhesive layer in which the first adhesive layer (which is obtained by applying the acrylic adhesive solution to form a film and drying the film) of the stack A, the base of the stack A, and the second adhesive layer (which is obtained by applying the acrylic adhesive solution on the embossed PET separator and drying the solution) are stacked in this order. PSA2-1 thus obtained is covered with PET separators on both sides.

<PSA2-2>

PSA2-2 was obtained in the same manner as PSA2-1, except that an embossed PET separator (thickness: 75 μm) embossed to have a pitch of 0.2×0.3 mm and an average peak height of 0.3 μm was used.

<PSA2-3>

PSA2-3 was obtained in the same manner as PSA2-1, except that an embossed PET separator (thickness: 75 μm) embossed to have a pitch of 0.2×0.3 mm and an average peak height of 0.5 μm was used.

<PSA2-4>

PSA2-4 was obtained in the same manner as PSA2-1, except that an embossed PET separator (thickness: 75 μm) embossed to have a pitch of 0.1×0.1 mm and an average peak height of 1.0 μm was used.

<PSA2-5>

PSA2-5 was obtained in the same manner as PSA2-1, except that an embossed PET separator (thickness: 75 μm) embossed to have a pitch of 2.0×2.0 mm and an average peak height of 1.0 μm was used.

<PSA2-6>

PSA2-6 was obtained in the same manner as PSA2-1, except that the acrylic adhesive solution diluted with toluene was applied on a PET base having a thickness of 4 μm to form a film having a thickness of 8 μm and that the acrylic adhesive solution was applied on the embossed PET separator to form a film having a thickness of 8 μm.

<Neofix5S2>

Neofix5S2 is double-coated adhesive tape having a total thickness of 5 μm, available from NICHIEI KAKOH CO., LTD. The second adhesive layer was measured for surface roughness, and found to be a not-so-rough adhesive having an Ra of 0.10 μm and an Rz of 1.20 μm.

<PSA3-1>

An adhesive layer was prepared by a method illustrated in FIG. 7. One of the separators was removed from Neofix5S2 available from NICHIEI KAKOH CO., LTD. to expose an adhesive face, and the rest of Neofix5S2 and an embossed PET separator having a thickness of 75 μm and a surface roughness of 0.55 μm in Ra and 3.41 μm in Rz were laminated in a manner such that the surface having the above surface roughness made contact with the exposed adhesive face (in Table 2, this is represented as “Embossed separator” in “Structure” of “Second adhesive layer”). In this way, PSA3-1 was obtained. Then, the embossed PET separator was removed, and the exposed adhesive face, which had an imprint of the embossed surface of the embossed PET separator formed therein, was bonded to another flat PET separator having one surface silicone-treated and having a thickness of 75 μm, in a manner such that the adhesive face and the silicone-treated surface were bonded together. It is noted that Neofix5S2 used here had been dried and had 0.3% of a solvent remaining therein. PSA3-1 is an adhesive layer in which the first adhesive layer (which is in contact with the other separator of Neofix5S2 remained unremoved), the base, and the second adhesive layer (which is an adhesive layer of Neofix5S2 provided with the embossed PET separator) are stacked in this order. PSA3-1 thus obtained is covered with PET separators on both sides.

<PSA3-2>

PSA3-2 was obtained in the same manner as PSA3-1, except that an embossed PET separator having a surface roughness of 0.06 μm in Ra and 0.30 μm in Rz was used.

<PSA3-3>

PSA3-3 was obtained in the same manner as PSA3-1, except that an embossed PET separator having a surface roughness of 0.30 μm in Ra and 2.90 μm in Rz was used.

<PSA3-4>

PSA3-4 was obtained in the same manner as PSA3-1, except that an embossed PET separator having a surface roughness of 0.70 μm in Ra and 5.10 μm in Rz was used.

<PSA3-5>

PSA3-5 was obtained in the same manner as PSA3-1, except that an embossed PET separator having a surface roughness of 1.00 μm in Ra and 10.00 μm in Rz was used.

<PSA4>

An adhesive containing an acrylic polymer as a main component was applied by printing in the form of circular particles 0.5 mm in outer diameter on a graphite film 1 (GS1) having a thickness of 32 μm, by pressing with a squeegee so that the particles of the adhesive would have a flat top face, have a pitch of 0.25 mm, and have a thickness of 6 μm (in Table 3, this structure is represented as “Dotted” in “Structure” of “Second adhesive layer”). The adhesive in the form of particles constitutes adhesive parts. It is noted, here, that the term “pitch of 0.25 mm” denotes the distance between adjacent circular adhesive parts (in Table 3, this is represented as “Distance between adhesive parts”). In PSA4, the adhesive parts occupied 34.9% of the total area of the adhesive layer. PSA4 indicates an adhesive material disposed on the obtained graphite film.

<PSA5>

PSA5 was obtained in the same manner as PSA4, except that the adhesive containing an acrylic polymer as a main component was applied by printing in the form of circular particles 0.5 mm in outer diameter so as to have a flat top face and have a pitch of 1.5 mm. In PSA5, the adhesive parts occupied 4.9% of the total area of the adhesive layer. PSA5 indicates an adhesive material disposed on the obtained graphite film.

### Production of Graphite Composite Film

### Examples 1 to 36, Comparative Example 1

Each graphite composite film was produced from: a graphite film (GS), a protective layer, and an application layer shown in Table 1; and an adhesive layer covered with PET separators on both sides shown in Tables 2 and 3. The adhesive layer of each of the obtained graphite composite films has a separator shown in Table 4 or 5 on its surface facing away from the graphite film. Note that the term “Flat” in Tables 2 and 3 means no projection/recess structures are provided. Specifically, a surface with an Ra of 0.13 μm or less and an Rz of 1.30 μm or less is smooth enough and is referred to as “Flat”. Further note that the term “normal PSA” in Table 2 means a three-layered adhesive including a first adhesive layer and a second adhesive layer which have no projection/recess structures. Tables 2 and 3 also show the percentage of the area of the graphite film covered with an adhesive relative to the total area of the graphite film (represented as “Percentage of area covered with adhesive (%)” in Tables 2 and 3).

Each graphite composite film was produced by stacking an adhesive layer covered with PET separators on both sizes, a graphite film (GS), a protective layer, and an application layer, each of which had a size of 100 mm×120 mm, in this order one by one from the adhesive layer, with the use of a laminator while ensuring that no air was trapped. In doing so, the PET separator in contact with the first adhesive layer of the adhesive layer was removed first, and then the adhesive layer and the graphite film were laminated so that the exposed adhesive face of the first adhesive layer and the graphite film contacted each other. That is, the adhesive layer and the graphite film were laminated so that the second adhesive layer was disposed oppositely from the graphite film. Then, the protective layer and the application layer were stacked in this order on the surface of the graphite film opposite the adhesive layer, such that a stack was obtained. Each stack thus obtained was cut into a size shown in Table 4 or 5 (70 mm×90 mm in Examples 1 to 28 and Comparative Example 1, 50 mm×50 mm in Examples 29, 32, and 34 to 36, and 15 mm×40 mm in Examples 30, 31, and 33). In this way, the graphite composite films were obtained.

TABLE 1

| | | | | | GS | | | |
|---|---|---|---|---|---|---|---|---|
| | | | | | | | Surface | |
| | Application layer | | Protective layer | | | | roughness | |
| | Model No. of | Thickness | Model No. of | Thickness | | Thickness | Ra | Rz |
| | application layer | μm | protective layer | μm | GS type | μm | μm | μm |
| Example 1 | H3200 by Nippa | 75 | GL-5B by NICHIEI | 5 | GS1 | 32 | 0.53 | 2.67 |
| Example 2 | H3200 by Nippa | 75 | GL-5B by NICHIEI | 5 | GS1 | 32 | 0.53 | 2.67 |
| Example 3 | H3200 by Nippa | 75 | GL-5B by NICHIEI | 5 | GS1 | 32 | 0.53 | 2.67 |
| Example 4 | H3200 by Nippa | 75 | GL-5B by NICHIEI | 5 | GS1 | 32 | 0.53 | 2.67 |
| Example 5 | H3200 by Nippa | 75 | GL-5B by NICHIEI | 5 | GS1 | 32 | 0.53 | 2.67 |
| Example 6 | H3200 by Nippa | 75 | GL-5B by NICHIEI | 5 | GS1 | 32 | 0.53 | 2.67 |
| Example 7 | H3200 by Nippa | 75 | GL-5B by NICHIEI | 5 | GS1 | 32 | 0.53 | 2.67 |
| Example 8 | H3200 by Nippa | 75 | GL-5B by NICHIEI | 5 | GS1 | 32 | 0.53 | 2.67 |
| Example 9 | H3200 by Nippa | 75 | GL-5B by NICHIEI | 5 | GS1 | 32 | 0.53 | 2.67 |
| Example 10 | H3200 by Nippa | 75 | GL-5B by NICHIEI | 5 | GS1 | 32 | 0.53 | 2.67 |
| Example 11 | H3200 by Nippa | 75 | GL-5B by NICHIEI | 5 | GS1 | 32 | 0.53 | 2.67 |
| Example 12 | H3200 by Nippa | 75 | GL-5B by NICHIEI | 5 | GS1 | 32 | 0.53 | 2.67 |
| Example 13 | H3200 by Nippa | 75 | GL-5B by NICHIEI | 5 | GS1 | 32 | 0.53 | 2.67 |
| Example 14 | H3200 by Nippa | 75 | GL-5B by NICHIEI | 5 | GS1 | 32 | 0.53 | 2.67 |
| Example 15 | H3200 by Nippa | 75 | GL-5B by NICHIEI | 5 | GS1 | 32 | 0.53 | 2.67 |
| Example 16 | H3200 by Nippa | 75 | GL-5B by NICHIEI | 5 | GS1 | 32 | 0.53 | 2.67 |
| Example 17 | H3200 by Nippa | 75 | GL-5B by NICHIEI | 5 | GS1 | 32 | 0.53 | 2.67 |
| Example 18 | H3200 by Nippa | 75 | GL-5B by NICHIEI | 5 | GS1 | 32 | 0.53 | 2.67 |
| Example 19 | H3200 by Nippa | 75 | GL-5B by NICHIEI | 5 | GS2 | 34 | 1.13 | 4.14 |
| Example 20 | H3200 by Nippa | 75 | GL-5B by NICHIEI | 5 | GS3 | 32 | 0.55 | 2.30 |
| Example 21 | H3200 by Nippa | 75 | GL-5B by NICHIEI | 5 | GS4 | 33 | 0.80 | 3.20 |
| Example 22 | H3200 by Nippa | 75 | GL-5B by NICHIEI | 5 | GS5 | 35 | 1.30 | 4.70 |
| Example 23 | H3200 by Nippa | 75 | GL-5B by NICHIEI | 5 | GS6 | 40 | 1.70 | 6.00 |
| Example 24 | H3200 by Nippa | 75 | GL-5B by NICHIEI | 5 | GS7 | 34 | 1.21 | 4.80 |
| Example 25 | H3200 by Nippa | 75 | GL-5B by NICHIEI | 5 | GS8 | 32 | 0.81 | 3.22 |
| Example 26 | H3200 by Nippa | 75 | GL-5B by NICHIEI | 5 | GS2 | 34 | 1.13 | 4.14 |
| Example 27 | H3200 by Nippa | 75 | GL-5B by NICHIEI | 5 | GS2 | 34 | 1.13 | 4.14 |
| Example 28 | H3200 by Nippa | 75 | GL-5B by NICHIEI | 5 | GS2 | 34 | 1.13 | 4.14 |
| Example 29 | H3200 by Nippa | 75 | GL-5B by NICHIEI | 5 | GS9 | 106 | 0.50 | 2.50 |
| Example 30 | H3200 by Nippa | 75 | GL-5B by NICHIEI | 5 | GS10 | 180 | 0.50 | 2.50 |
| Example 31 | H3200 by Nippa | 75 | GL-5B by NICHIEI | 5 | GS11 | 550 | 0.50 | 2.50 |
| Example 32 | H3200 by Nippa | 75 | GL-5B by NICHIEI | 5 | GS12 | 143 | 0.50 | 2.50 |
| Example 33 | H3200 by Nippa | 75 | GL-5B by NICHIEI | 5 | GS13 | 365 | 0.50 | 2.50 |
| Example 34 | H3200 by Nippa | 75 | GL-5B by NICHIEI | 5 | GS9 | 106 | 0.50 | 2.50 |
| Example 35 | H3200 by Nippa | 75 | GL-5B by NICHIEI | 5 | GS9 | 106 | 0.50 | 2.50 |
| Example 36 | H3200 by Nippa | 75 | GL-5B by NICHIEI | 5 | GS14 | 200 | 0.61 | 3.07 |
| Comparative | H3200 by Nippa | 75 | GL-5B by NICHIEI | 5 | GS1 | 32 | 0.53 | 2.67 |
| Example 1 | | | | | | | | |
| Comparative | H3200 by Nippa | 75 | GL-5B by NICHIEI | 5 | GS1 | 32 | 0.53 | 2.67 |
| Example 2 | | | | | | | | |
| Comparative | H3200 by Nippa | 75 | GL-5B by NICHIEI | 5 | GS1 | 32 | 0.53 | 2.67 |
| Example 3 | | | | | | | | |
| Reference | H3200 by Nippa | 75 | GL-5B by NICHIEI | 5 | GS1 | 32 | 0.53 | 2.67 |
| Example 1 | | | | | | | | |
| Reference | H3200 by Nippa | 75 | GL-5B by NICHIEI | 5 | GS9 | 106 | 0.50 | 2.50 |
| Example 2 | | | | | | | | |

TABLE 2

| | Adhesive layer | | | | | | | | | | | |
|---|---|---|---|---|---|---|---|---|---|---|---|---|
| | | | | | | | Second adhesive layer | | | | | |
| | | | First | | | | | | Surface | | | Percentage |
| | | | adhesive | | | | | | roughness | | | of area |
| | | Total | layer | | Base | | | | of adhesive | | | covered |
| | Type of | thick- | Thick- | | Thick- | | Thick- | | layer | | | with |
| | adhesive | ness | ness | Struc- | ness | Mate- | ness | | Ra | Rz | | adhesive |
| | layer | μm | μm | ture | μm | rial | μm | Structure | (μm) | (μm) | Characteristics | (%) |
| Ex. 1 | PSA1-1 | 6 | 2 | Flat | 2 | PET | 2 | Island-like | 0.39 | 2.90 | Island-like projections are 1.3 mm | 76.1 |
| | | | | | | | | projections | | | on a side, Distance | |
| | | | | | | | | | | | between island-like | |
| | | | | | | | | | | | projections is 0.19 mm, | |
| | | | | | | | | | | | Adhesive part area is 76.1% | |
| Ex. 2 | PSA1-2 | 6 | 2 | Flat | 2 | PET | 2 | Island-like | 0.41 | 3.20 | Island-like projections are 1.3 mm | 35.6 |
| | | | | | | | | projections | | | on a side, Distance | |
| | | | | | | | | | | | between island-like | |
| | | | | | | | | | | | projections is 0.88 mm, | |
| | | | | | | | | | | | Adhesive part area is 35.6% | |
| Ex. 3 | PSA1-3 | 6 | 2 | Flat | 2 | PET | 2 | Island-like | 0.40 | 3.15 | Island-like projections are 1.3 mm | 52.2 |
| | | | | | | | | projections | | | on a side, Distance | |
| | | | | | | | | | | | between island-like | |
| | | | | | | | | | | | projections is 0.50 mm, | |
| | | | | | | | | | | | Adhesive part area is 52.2% | |
| Ex. 4 | PSA1-4 | 6 | 2 | Flat | 2 | PET | 2 | Island-like | 0.33 | 2.67 | Island-like projections are | 85.0 |
| | | | | | | | | projections | | | 2.25 mm on a side, Distance | |
| | | | | | | | | | | | between island-like | |
| | | | | | | | | | | | projections is 0.88 mm, | |
| | | | | | | | | | | | Adhesive part area is 85.0% | |
| Ex. 5 | PSA1-5 | 6 | 2 | Flat | 2 | PET | 2 | Inland-like | 0.29 | 2.56 | Island-like projections are 3.5 mm | 90.0 |
| | | | | | | | | projections | | | on a side, Distance | |
| | | | | | | | | | | | between island-like | |
| | | | | | | | | | | | projections is 0.19 mm, | |
| | | | | | | | | | | | Adhesive part area is 90.0% | |
| Ex. 6 | PSA1-6 | 6 | 2 | Flat | 2 | PET | 2 | Island-like | 0.37 | 2.92 | Island-like projections are 0.7 mm | 76.6 |
| | | | | | | | | projections | | | on a side, Distance | |
| | | | | | | | | | | | between island-like | |
| | | | | | | | | | | | projections is 0.1 mm, | |
| | | | | | | | | | | | Adhesive part area is 76.6% | |
| Ex. 7 | PSA1-7 | 6 | 2 | Flat | 2 | PET | 2 | Island-like | 0.38 | 2.98 | Island-like projections are | 76.6 |
| | | | | | | | | projections | | | 0.07 mm on a side, Distance | |
| | | | | | | | | | | | between island-like | |
| | | | | | | | | | | | projections is 0.01 mm, | |
| | | | | | | | | | | | Adhesive part area is 76.6% | |
| Ex. 8 | PSA2-1 | 6 | 2 | Flat | 2 | PET | 2 | Grooves in | 0.41 | 3.25 | Pitch is 0.2 × 0.3 mm, Average | 100 |
| | | | | | | | | lattice-like | | | depth of grooves is 1.0 μm | |
| | | | | | | | | pattern | | | | |
| Ex. 9 | PSA2-2 | 6 | 2 | Flat | 2 | PET | 2 | Grooves in | 0.22 | 2.84 | Pitch is 0.2 × 0.3 mm, Average | 100 |
| | | | | | | | | lattice-like | | | depth of grooves is 0.3 μm | |
| | | | | | | | | pattern | | | | |
| Ex. | PSA2-3 | 6 | 2 | Flat | 2 | PET | 2 | Grooves in | 0.35 | 3.01 | Pitch is 0.2 × 0.3 mm, Average | 100 |
| 10 | | | | | | | | lattice-like | | | depth of grooves is 0.5 μm | |
| | | | | | | | | pattern | | | | |
| Ex. | PSA2-4 | 6 | 2 | Flat | 2 | PET | 2 | Grooves in | 0.42 | 3.13 | Pitch is 0.1 × 0.1 mm, Average | 100 |
| 11 | | | | | | | | lattice-like | | | depth of grooves is 1.0 μm | |
| | | | | | | | | pattern | | | | |
| Ex. | PSA2-5 | 6 | 2 | Flat | 2 | PET | 2 | Grooves in | 0.35 | 2.98 | Pitch is 2.0 × 2.0 mm, Average | 100 |
| 12 | | | | | | | | lattice-like | | | depth of grooves is 1.0 μm | |
| | | | | | | | | pattern | | | | |
| Ex. | PSA2-6 | 20 | 8 | Flat | 4 | PET | 8 | Grooves in | 0.42 | 3.30 | Pitch is 0.2 × 0.3 mm, Average | 100 |
| 13 | | | | | | | | lattice-like | | | depth of grooves is 1.0 μm | |
| | | | | | | | | pattern | | | | |
| Ex. | PSA3-1 | 5 | 1.5 | Flat | 2 | PET | 1.5 | Embossed | 0.49 | 3.43 | Dried normal PSA separator | 100 |
| 14 | | | | | | | | separator | | | (containing 0.3% of solvent | |
| | | | | | | | | | | | remaining therein) is replaced | |
| | | | | | | | | | | | with embossed separator | |
| Ex. | PSA3-2 | 5 | 1.5 | Flat | 2 | PET | 1.5 | Embossed | 0.15 | 1.82 | Dried normal PSA separator | 100 |
| 15 | | | | | | | | separator | | | (containing 0.3% of solvent | |
| | | | | | | | | | | | remaining therein) is replaced | |
| | | | | | | | | | | | with embossed separator | |
| Ex. | PSA3-3 | 5 | 1.5 | Flat | 2 | PET | 1.5 | Embossed | 0.38 | 2.96 | Dried normal PSA separator | 100 |
| 16 | | | | | | | | separator | | | (containing 0.3% of solvent | |
| | | | | | | | | | | | remaining therein) is replaced | |
| | | | | | | | | | | | with embossed separator | |
| Ex. | PSA3-4 | 5 | 1.5 | Flat | 2 | PET | 1.5 | Embossed | 0.58 | 3.88 | Dried normal PSA separator | 100 |
| 17 | | | | | | | | separator | | | (containing 0.3% of solvent | |
| | | | | | | | | | | | remaining therein) is replaced | |
| | | | | | | | | | | | with embossed separator | |
| Ex. | PSA3-5 | 5 | 1.5 | Flat | 2 | PET | 1.5 | Embossed | 0.79 | 8.23 | Dried normal PSA separator | 100 |
| 18 | | | | | | | | separator | | | (containing 0.3% of solvent | |
| | | | | | | | | | | | remaining therein) is replaced | |
| | | | | | | | | | | | with embossed separator | |
| Ex. | Neofix | 5 | 1.5 | Flat | 2 | PET | 1.5 | Flat | 0.10 | 1.20 | — | 100 |
| 19 | 5S2 by | | | | | | | | | | | |
| | NICHIEI | | | | | | | | | | | |
| Ex. | Neofix | 5 | 1.5 | Flat | 2 | PET | 1.5 | Flat | 0.10 | 1.20 | — | 100 |
| 20 | 5S2 by | | | | | | | | | | | |
| | NICHIEI | | | | | | | | | | | |
| Ex. | Neofix | 5 | 1.5 | Flat | 2 | PET | 1.5 | Flat | 0.10 | 1.20 | — | 100 |
| 21 | 5S2 by | | | | | | | | | | | |
| | NICHIEI | | | | | | | | | | | |
| Ex. | Neofix | 5 | 1.5 | Flat | 2 | PET | 1.5 | Flat | 0.10 | 1.20 | — | 100 |
| 22 | 5S2 by | | | | | | | | | | | |
| | NICHIEI | | | | | | | | | | | |
| Ex. | Neofix | 5 | 1.5 | Flat | 2 | PET | 1.5 | Flat | 0.10 | 1.20 | — | 100 |
| 23 | 5S2 by | | | | | | | | | | | |
| | NICHIEI | | | | | | | | | | | |
| Ex. | Neofix | 5 | 1.5 | Flat | 2 | PET | 1.5 | Flat | 0.10 | 1.20 | — | 100 |
| 24 | 5S2 by | | | | | | | | | | | |
| | NICHIEI | | | | | | | | | | | |
| Ex. | Neofix | 5 | 1.5 | Flat | 2 | PET | 1.5 | Flat | 0.10 | 1.20 | — | 100 |
| 25 | 5S2 by | | | | | | | | | | | |
| | NICHIEI | | | | | | | | | | | |

Note:
“Ex.” stands for “Examples”

TABLE 3

| | Adhesive layer | | | | | | | | | | | |
|---|---|---|---|---|---|---|---|---|---|---|---|---|
| | | | | | | | Second adhesive layer | | | | | |
| | | | First | | | | | | Surface | | | Percentage |
| | | | adhesive | | | | | | roughness of | | | of area |
| | | Total | layer | | Base | | | | adhesive | | | covered |
| | Type of | thick- | Thick- | | Thick- | | Thick- | | layer | | | with |
| | adhesive | ness | ness | Struc- | ness | | ness | | Ra | Rz | | adhesive |
| | layer | μm | μm | ture | μm | Material | μm | Structure | (μm) | (μm) | Characteristics | (%) |
| Ex. | PSA1-1 | 6 | 2 | Flat | 2 | PET | 2 | Island-like | 0.39 | 2.90 | Island-like projections are 1.3 mm | 76.1 |
| 26 | | | | | | | | projections | | | on a side, Distance | |
| | | | | | | | | | | | between island-like projections | |
| | | | | | | | | | | | is 0.19 mm, and Adhesive part | |
| | | | | | | | | | | | area is 76.1% | |
| Ex. | PSA2-1 | 6 | 2 | Flat | 2 | PET | 2 | Grooves in | 0.41 | 3.25 | Pitch is 0.2 × 0.3 mm, Average | 100 |
| 27 | | | | | | | | lattice-like | | | depth of grooves is 1.0 μm | |
| | | | | | | | | pattern | | | | |
| Ex. | PSA3-1 | 5 | 1.5 | Flat | 2 | PET | 1.5 | Embossed | 0.49 | 3.43 | Dried normal PSA separator | 100 |
| 28 | | | | | | | | separator | | | (containing 0.3% of solvent | |
| | | | | | | | | | | | remaining therein) is replaced | |
| | | | | | | | | | | | with embossed separator | |
| Ex. | PSA2-1 | 6 | 2 | Flat | 2 | PET | 2 | Grooves in | 0.41 | 3.25 | Pitch is 0.2 × 0.3 mm, Average | 100 |
| 29 | | | | | | | | lattice-like | | | depth of grooves is 1.0 μm | |
| | | | | | | | | pattern | | | | |
| Ex. | PSA2-1 | 6 | 2 | Flat | 2 | PET | 2 | Grooves in | 0.41 | 3.25 | Pitch is 0.2 × 0.3 mm, Average | 100 |
| 30 | | | | | | | | lattice-like | | | depth of grooves is 1.0 μm | |
| | | | | | | | | pattern | | | | |
| Ex. | PSA2-1 | 6 | 2 | Flat | 2 | PET | 2 | Grooves in | 0.41 | 3.25 | Pitch is 0.2 × 0.3 mm, Average | 100 |
| 31 | | | | | | | | lattice-like | | | depth of grooves is 1.0 μm | |
| | | | | | | | | pattern | | | | |
| Ex. | PSA2-1 | 6 | 2 | Flat | 2 | PET | 2 | Grooves in | 0.41 | 3.25 | Pitch is 0.2 × 0.3 mm, Average | 100 |
| 32 | | | | | | | | lattice-like | | | depth of grooves is 1.0 μm | |
| | | | | | | | | pattern | | | | |
| Ex. | PSA2-1 | 6 | 2 | Flat | 2 | PET | 2 | Grooves in | 0.41 | 3.25 | Pitch is 0.2 × 0.3 mm, Average | 100 |
| 33 | | | | | | | | lattice-like | | | depth of grooves is 1.0 μm | |
| | | | | | | | | pattern | | | | |
| Ex. | PSA1-1 | 6 | 2 | Flat | 2 | PET | 2 | Island-like | 0.39 | 2.90 | Island-like projections are 1.3 mm | 76.1 |
| 34 | | | | | | | | projections | | | on a side, Distance | |
| | | | | | | | | | | | between island-like projections | |
| | | | | | | | | | | | is 0.19 mm, Adhesive part | |
| | | | | | | | | | | | area is 76.1% | |
| Ex. | PSA3-1 | 5 | 1.5 | Flat | 2 | PET | 1.5 | Embossed | 0.49 | 3.43 | Dried normal PSA separator | 100 |
| 35 | | | | | | | | separator | | | (containing 0.3% of solvent | |
| | | | | | | | | | | | remaining therein) is replaced | |
| | | | | | | | | | | | with embossed separator | |
| Ex. | PSA2-1 | 6 | 2 | Flat | 2 | PET | 2 | Grooves in | 0.41 | 3.25 | Pitch is 0.2 × 0.3 mm, Average | 100 |
| 36 | | | | | | | | lattice-like | | | depth of grooves is 1.0 μm | |
| | | | | | | | | pattern | | | | |
| Com. | Neofix | 5 | 1.5 | Flat | 2 | PET | 1.5 | Flat | 0.10 | 1.20 | — | 100 |
| Ex. 1 | 5S2 by | | | | | | | | | | | |
| | NICHIEI | | | | | | | | | | | |
| Com. | PSA4 | 6 | None | — | None | None | 6 | Dotted | 0.19 | 3.60 | φ0.5 mm, Distance between | 34.9 |
| Ex. 2 | | | | | | | | | | | adhesive parts is 0.25 mm, | |
| | | | | | | | | | | | Adhesive part area is 34.9% | |
| Com. | PSA5 | 6 | None | — | None | None | 6 | Dotted | 0.10 | 3.30 | φ0.5 mm, Distance between | 4.9 |
| Ex. 3 | | | | | | | | | | | adhesive parts is 1.5 mm, | |
| | | | | | | | | | | | Adhesive part area is 4.9% | |
| Ref. | Neofix | 5 | 1.5 | Flat | 2 | PET | 1.5 | Flat | 0.10 | 1.20 | — | 100 |
| Ex. 1 | 5S2 by | | | | | | | | | | | |
| | NICHIEI | | | | | | | | | | | |
| Ref. | PSA2-1 | 6 | 2 | Flat | 2 | PET | 2 | Grooves in | 0.41 | 3.25 | Pitch is 0.2 × 0.3 mm, Average | 100 |
| Ex. 2 | | | | | | | | lattice-like | | | depth of grooves is 1.0 μm | |
| | | | | | | | | pattern | | | | |

Note:
“Ex.” stands for “Examples”,
“Com. Ex.” stands for “Comparative Example,”
“Ref. Ex.” stands for “Reference Example”

TABLE 4

| | | | | Graphite composite film | | | | | | |
|---|---|---|---|---|---|---|---|---|---|---|
| | | | | | Surface | | Surface | | | |
| | | | | | roughness | | roughness | | | |
| | Separator | | | Total | of | | of attached | | | |
| | | Surface | | thickness | adhesive | | protective | | | |
| | | roughness | | without | layer | | layer | | | Peel |
| | Thickness | Ra | Rz | separator | Ra | Rz | Ra | Rz | Size | strength |
| | μm | μm | μm | μm | μm | μm | μm | μm | mm | N/25 mm |
| Ex. 1 | 75 | 0.05 | 0.29 | 118 | 0.42 | 3.60 | 0.20 | 1.70 | 70 × 90 | 6.0 |
| Ex. 2 | 75 | 0.05 | 0.29 | 118 | 0.44 | 4.20 | — | — | 70 × 90 | 4.0 |
| Ex. 3 | 75 | 0.05 | 0.29 | 118 | 0.43 | 4.10 | — | — | 70 × 90 | 5.0 |
| Ex. 4 | 75 | 0.05 | 0.29 | 118 | 0.37 | 3.42 | — | — | 70 × 90 | 6.5 |
| Ex. 5 | 75 | 0.05 | 0.29 | 118 | 0.34 | 3.35 | — | — | 70 × 90 | 6.8 |
| Ex. 6 | 75 | 0.05 | 0.29 | 118 | 0.41 | 3.56 | — | — | 70 × 90 | 6.0 |
| Ex. 7 | 75 | 0.05 | 0.29 | 118 | 0.41 | 3.58 | — | — | 70 × 90 | 6.0 |
| Ex. 8 | 75 | 0.05 | 0.29 | 118 | 0.45 | 4.08 | 0.21 | 1.90 | 70 × 90 | 6.0 |
| Ex. 9 | 75 | 0.05 | 0.29 | 118 | 0.32 | 3.54 | — | — | 70 × 90 | 6.8 |
| Ex. | 75 | 0.05 | 0.29 | 118 | 0.39 | 3.89 | — | — | 70 × 90 | 6.4 |
| 10 | | | | | | | | | | |
| Ex. | 75 | 0.05 | 0.29 | 118 | 0.46 | 4.00 | — | — | 70 × 90 | 4.5 |
| 11 | | | | | | | | | | |
| Ex. | 75 | 0.05 | 0.29 | 118 | 0.40 | 3.92 | — | — | 70 × 90 | 6.5 |
| 12 | | | | | | | | | | |
| Ex. | 75 | 0.05 | 0.29 | 132 | 0.46 | 4.15 | — | — | 70 × 90 | 8.0 |
| 13 | | | | | | | | | | |
| Ex. | 75 | 0.55 | 3.41 | 117 | 0.60 | 4.50 | 0.25 | 2.00 | 70 × 90 | 6.5 |
| 14 | | | | | | | | | | |
| Ex. | 75 | 0.06 | 0.30 | 117 | 0.19 | 2.32 | — | — | 70 × 90 | 6.9 |
| 15 | | | | | | | | | | |
| Ex. | 75 | 0.30 | 2.90 | 117 | 0.43 | 3.52 | — | — | 70 × 90 | 6.6 |
| 16 | | | | | | | | | | |
| Ex. | 75 | 0.70 | 5.10 | 117 | 0.67 | 4.67 | — | — | 70 × 90 | 6.2 |
| 17 | | | | | | | | | | |
| Ex. | 75 | 1.00 | 10.00 | 117 | 0.82 | 9.23 | — | — | 70 × 90 | 4.5 |
| 18 | | | | | | | | | | |
| Ex. | 75 | 0.05 | 0.29 | 119 | 0.40 | 3.52 | 0.18 | 1.50 | 70 × 90 | 6.3 |
| 19 | | | | | | | | | | |
| Ex. | 75 | 0.05 | 0.29 | 117 | 0.20 | 2.40 | — | — | 70 × 90 | 6.9 |
| 20 | | | | | | | | | | |
| Ex. | 75 | 0.05 | 0.29 | 118 | 0.35 | 3.23 | — | — | 70 × 90 | 6.5 |
| 21 | | | | | | | | | | |
| Ex. | 75 | 0.05 | 0.29 | 120 | 0.53 | 3.90 | — | — | 70 × 90 | 6.0 |
| 22 | | | | | | | | | | |
| Ex. | 75 | 0.05 | 0.29 | 125 | 0.72 | 4.32 | — | — | 70 × 90 | 5.2 |
| 23 | | | | | | | | | | |
| Ex. | 75 | 0.05 | 0.29 | 119 | 0.31 | 2.42 | — | — | 70 × 90 | 6.8 |
| 24 | | | | | | | | | | |
| Ex. | 75 | 0.05 | 0.29 | 117 | 0.33 | 2.36 | — | — | 70 × 90 | 6.7 |
| 25 | | | | | | | | | | |

| | Evaluation | | | | | |
|---|---|---|---|---|---|---|
| | | | | | Cost | |
| | | | Heat | Evaluation | for | |
| | Bubble | Evaluation | dissipation | of | adhesive | Adhesion |
| | evaluation | of adhesiveness | test | reworkability | layer | stability |
| Ex. 1 | 5 | 4 | 4 | 3 | 3 | 3 |
| Ex. 2 | 5 | 2 | 2 | 3 | 3 | 3 |
| Ex. 3 | 5 | 3 | 3 | 3 | 3 | 3 |
| Ex. 4 | 3 | 5 | 5 | 3 | 3 | 3 |
| Ex. 5 | 2 | 5 | 5 | 3 | 3 | 3 |
| Ex. 6 | 4 | 4 | 4 | 3 | 3 | 3 |
| Ex. 7 | 2 | 4 | 4 | 3 | 3 | 3 |
| Ex. 8 | 4 | 5 | 5 | 3 | 3 | 4 |
| Ex. 9 | 2 | 5 | 5 | 3 | 3 | 4 |
| Ex. | 3 | 5 | 5 | 3 | 3 | 4 |
| 10 | | | | | | |
| Ex. | 4 | 2 | 2 | 3 | 3 | 4 |
| 11 | | | | | | |
| Ex. | 2 | 5 | 5 | 3 | 3 | 4 |
| 12 | | | | | | |
| Ex. | 4 | 2 | 2 | 3 | 3 | 4 |
| 13 | | | | | | |
| Ex. | 4 | 5 | 5 | 3 | 4 | 4 |
| 14 | | | | | | |
| Ex. | 2 | 5 | 5 | 3 | 4 | 4 |
| 15 | | | | | | |
| Ex. | 3 | 5 | 5 | 3 | 4 | 4 |
| 16 | | | | | | |
| Ex. | 5 | 4 | 4 | 3 | 4 | 4 |
| 17 | | | | | | |
| Ex. | 5 | 2 | 2 | 3 | 4 | 4 |
| 18 | | | | | | |
| Ex. | 3 | 4 | 4 | 3 | 5 | 4 |
| 19 | | | | | | |
| Ex. | 2 | 5 | 5 | 3 | 5 | 4 |
| 20 | | | | | | |
| Ex. | 3 | 5 | 5 | 3 | 5 | 4 |
| 21 | | | | | | |
| Ex. | 4 | 4 | 3 | 3 | 5 | 4 |
| 22 | | | | | | |
| Ex. | 5 | 3 | 2 | 3 | 5 | 4 |
| 23 | | | | | | |
| Ex. | 2 | 5 | 4 | 3 | 5 | 4 |
| 24 | | | | | | |
| Ex. | 2 | 5 | 4 | 3 | 5 | 4 |
| 25 | | | | | | |

Note:
“Ex.” stands for “Example”

TABLE 5

| | | | | Graphite composite film | | | | | | |
|---|---|---|---|---|---|---|---|---|---|---|
| | | | | | | | Surface | | | |
| | | | | | Surface | | roughness | | | |
| | Separator | | | Total | roughness | | of attached | | | |
| | | Surface | | thickness | of adhesive | | protective | | | |
| | | roughness | | without | layer | | layer | | | Peel |
| | Thickness | Ra | Rz | separator | Ra | Rz | Ra | Rz | Size | strength |
| | μm | μm | μm | μm | μm | μm | μm | μm | mm | N/25 mm |
| Ex. | 75 | 0.05 | 0.29 | 120 | 0.52 | 4.60 | — | — | 70 × 90 | 4.5 |
| 26 | | | | | | | | | | |
| Ex. | 75 | 0.05 | 0.29 | 120 | 0.55 | 5.08 | — | — | 70 × 90 | 4.5 |
| 27 | | | | | | | | | | |
| Ex. | 75 | 0.55 | 3.41 | 119 | 0.65 | 5.50 | — | — | 70 × 90 | 4.5 |
| 28 | | | | | | | | | | |
| Ex. | 75 | 0.05 | 0.29 | 192 | 0.40 | 3.50 | 0.11 | 0.95 | 50 × 50 | — |
| 29 | | | | | | | | | | |
| Ex. | 75 | 0.05 | 0.29 | 266 | 0.39 | 3.40 | 0.10 | 0.90 | 15 × 40 | — |
| 30 | | | | | | | | | | |
| Ex. | 75 | 0.05 | 0.29 | 636 | 0.38 | 3.30 | 0.10 | 0.90 | 15 × 40 | — |
| 31 | | | | | | | | | | |
| Ex. | 75 | 0.05 | 0.29 | 229 | 0.39 | 3.40 | 0.10 | 0.90 | 50 × 50 | — |
| 32 | | | | | | | | | | |
| Ex. | 75 | 0.05 | 0.29 | 451 | 0.38 | 3.30 | 0.10 | 0.90 | 15 × 40 | — |
| 33 | | | | | | | | | | |
| Ex. | 75 | 0.05 | 0.29 | 192 | 0.37 | 3.10 | 0.10 | 0.85 | 50 × 50 | — |
| 34 | | | | | | | | | | |
| Ex. | 75 | 0.55 | 3.41 | 191 | 0.50 | 4.00 | 0.11 | 0.98 | 50 × 50 | — |
| 35 | | | | | | | | | | |
| Ex. | 75 | 0.05 | 0.29 | 286 | 0.40 | 3.50 | 0.11 | 0.95 | 50 × 50 | — |
| 36 | | | | | | | | | | |
| Com. | 75 | 0.05 | 0.29 | 117 | 0.18 | 1.58 | 0.09 | 0.70 | 70 × 90 | 7.0 |
| Ex. 1 | | | | | | | | | | |
| Com. | 75 | 0.05 | 0.29 | 118 | 0.45 | 4.30 | 0.08 | 0.65 | 70 × 90 | 3.7 |
| Ex. 2 | | | | | | | | | | |
| Com. | 75 | 0.05 | 0.29 | 118 | 0.18 | 4.00 | 0.05 | 0.50 | 70 × 90 | 0.2 |
| Ex. 3 | | | | | | | | | | |
| Ref. | 75 | 0.05 | 0.29 | 117 | 0.18 | 1.58 | 0.09 | 0.70 | 40 × 60 | 7.0 |
| Ex. 1 | | | | | | | | | | |
| Ref. | 75 | 0.05 | 0.29 | 192 | 0.40 | 3.50 | 0.09 | 0.80 | 15 × 15 | — |
| Ex. 2 | | | | | | | | | | |

| | Evaluation | | | | | |
|---|---|---|---|---|---|---|
| | | | | | Cost | |
| | | Evaluation | Heat | | for | |
| | Bubble | of | dissipation | Evaluation | adhesive | Adhesion |
| | evaluation | of adhesiveness | test | reworkability | layer | stability |
| Ex. | 5 | 2 | 2 | 3 | 3 | 3 |
| 26 | | | | | | |
| Ex. | 5 | 2 | 2 | 3 | 3 | 4 |
| 27 | | | | | | |
| Ex. | 5 | 2 | 2 | 3 | 4 | 4 |
| 28 | | | | | | |
| Ex. | 5 | — | 5 | 3 | 3 | 4 |
| 29 | | | | | | |
| Ex. | 5 | — | 5 | 3 | 3 | 4 |
| 30 | | | | | | |
| Ex. | 5 | — | 5 | 3 | 3 | 4 |
| 31 | | | | | | |
| Ex. | 5 | — | 5 | 3 | 3 | 4 |
| 32 | | | | | | |
| Ex. | 5 | — | 5 | 3 | 3 | 4 |
| 33 | | | | | | |
| Ex. | 5 | — | 5 | 3 | 3 | 3 |
| 34 | | | | | | |
| Ex. | 5 | — | 5 | 3 | 4 | 4 |
| 35 | | | | | | |
| Ex. | 5 | — | 5 | 3 | 3 | 4 |
| 36 | | | | | | |
| Com. | 1 | 5 | 5 | 2 | 5 | 2 |
| Ex. 1 | | | | | | |
| Com. | 5 | 1 | 1 | 1 | 5 | 1 |
| Ex. 2 | | | | | | |
| Com. | 5 | 1 | 1 | 1 | 5 | 1 |
| Ex. 3 | | | | | | |
| Ref. | 5 | 5 | 1 | 3 | 5 | 4 |
| Ex. 1 | | | | | | |
| Ref. | 5 | — | 1 | 3 | 3 | 4 |
| Ex. 2 | | | | | | |

Note:
“Ex.” stands for “Examples”,
“Com. Ex.” stands for “Comparative Example,”
“Ref. Ex.” stands for “Reference Example”

### Comparative Example 2

A graphite composite film of Comparative Example 2 was prepared in the same manner as described in Example 1, except that the adhesive containing an acrylic polymer as a main component was applied by printing in the form of circular particles 0.5 mm in outer diameter on a graphite film 1 having a thickness of 32 μm, by pressing with a squeegee so that the particles of the adhesive would have a flat top face, have a pitch of 0.25 mm, and have a thickness of 6 μm, and then a PET separator of 75 μm was attached.

### Comparative Example 3

A graphite composite film of Comparative Example 3 was prepared in the same manner as described in Example 1, except that the adhesive containing an acrylic polymer as a main component was applied by printing in the form of circular particles 0.5 mm in outer diameter on a graphite film 1 having a thickness of 32 μm, by pressing with a squeegee so that the particles of the adhesive would have a flat top face, have a pitch of 1.5 mm, and have a thickness of 6 μm, and then a PET separator of 75 μm was attached.

### Reference Example 1

A graphite composite film was prepared in the same manner as described in Comparative Example 1, except that the stack was cut into a size of 40 mm×60 mm.

### Reference Example 2

A graphite composite film was prepared in the same manner as described in Example 29, except that the stack was cut into a size of 15 mm×15 mm.

[Evaluation of Graphite Composite Film]

The graphite composite films obtained in Examples, Comparative Example, and Reference Examples were evaluated for the following properties. The results are shown in Tables 4 and 5.

<Peel Strength>

A physical property “peel strength”, which indicates the adhesion force of a graphite composite film, was determined in accordance with JIS-Z0237, method 1 (“Method for testing adhesion force in 180° peeling from test plate”). A SUS plate (width: 50 mm; length: 125 mm; thickness: 1.1 mm; surface roughness Ra: 50 nm) as described in JIS-Z0237 was cleaned with methanol. A separator (i.e., the separator in contact with the second adhesive layer) was removed from the graphite composite film cut in a size of 25 mm×120 mm. A 2 kg roller was used to attach the graphite composite film to the SUS plate thus cleaned. Specifically, the roller was rolled back and forth over the graphite composite film twice in a manner such that the second adhesive layer and the SUS plate were in contact with each other while ensuring that no air was trapped between the graphite composite film and the SUS plate. This was performed under the conditions in which the ambient temperature was 23° C. and humidity was 50%. The graphite composite film was then left for 1 hour. Thereafter, an Autograph (model number: AG-10 TB) and a 50 N load cell (model number: SBL-50N), each manufactured by SIMAZU were used to pull the graphite composite film, under the same temperature and humidity conditions as above, at a rate of 300 mm/min., and the 180° peeling adhesion force was measured. The same measurement was performed three times using different test pieces, and the mean of the results of the three measurements was rounded to the nearest thousandth. The value thus obtained was used as a peel strength (unit: N/25 mm).

<Bubble Evaluation>

An evaluation was performed to determine the degree of reduction of bubbles that would be trapped between an adherend and a graphite composite film when the adherend and the graphite composite film are bonded together. The evaluation was performed in the following manner.

Adherend: a SUS plate having a size of 80 mm×100 mm and a thickness of 0.2 mm (cleaned with methanol)

Environment: conditions in which ambient temperature is 23° C. and humidity is 50%

Number of measurements: 10 (measurement is performed 10 times and the most frequently obtained one of the following grades is used as the measurement result.)

Procedures: A PET separator was removed from a graphite composite film. The graphite composite film was held on a flat table with the exposed adhesive face of the second adhesive layer facing up. An adherend was placed on the adhesive face of the graphite composite film in a manner such that the to-be-bonded face of the adherend was brought into contact with the adhesive face of the graphite composite film in one go, and a weight of 5 kg (having a size of 80 mm×100 mm) was placed and left for 10 seconds. Then, a rubber roller weighing 10 kg was rolled back and forth on the adherend three times to remove air bubbles. Then, the film was checked for any remaining air bubbles and evaluated on the following scale. It is noted that the air bubbles appearing on a surface of the adherend constitute raised bumps. Therefore, the size and presence of an air bubble can be evaluated by measuring the maximum length (in a case of an oval shape, the longest distance of the raised bump is measured) of the largest one of the air bubbles which look like raised bumps on the surface and then evaluating the measured length on the following scale.

Grade 1: an air bubble of 6.0 mm or greater is present

Grade 2: an air bubble of 2.5 mm or greater and less than 6.0 mm is present

Grade 3: an air bubble of 1.5 mm or greater and less than 2.5 mm is present

Grade 4: an air bubble less than 1.5 mm is present

Grade 5: no air bubbles are present

<Evaluation of Adhesiveness>

The adhesiveness of each graphite composite film was evaluated by categorizing the results of testing on the peel strength of each graphite composite film as below.

Grade 1: less than 4.0 N/25 mm

Grade 2: 4.0 N/25 mm or greater and less than 5.0 N/25 mm

Grade 3: 5.0 N/25 mm or greater and less than 6.0 N/25 mm

Grade 4: 6.0 N/25 mm or greater and less than 6.5 N/25 mm

Grade 5: 6.5 N/25 mm or greater

<Heat Dissipation Test>

The following heat dissipation test was performed to evaluate the heat dissipation ability of each graphite composite film. FIG. 8 shows the structure of a system for use in performing a heat dissipation test on a graphite composite film. Aside from the bubble evaluation, a PET separator was removed from the graphite composite film, and a SUS plate 33 having a size of 80 mm×100 mm and a thickness of 0.2 mm and a graphite film 35 were bonded together with the use of a laminator in a manner such that the SUS plate and the exposed adhesive face of an adhesive layer 34 were brought into contact with each other in one go. The application layer was also removed, and then a ceramic heater (whose heater face had been spray-coated with a black body with an emissivity of 0.94) having a size of 10 mm×10 mm×1 mm, which serves as a heat generating component 37, was attached to the central portion of the graphite composite film so as to make contact with a protective layer 36, and was heated with a power of 2 W until the temperature rise became saturated. The heat dissipation test was performed under the conditions in which the ambient temperature was 23° C. and humidity was 50%, with a wind block provided around the system to prevent temperature change caused by air flow. The temperature measurement was performed by measuring the surface temperature of the heater with the use of a thermoviewer. The measurement was performed five times, and the mean of the five values was used as a measured value. The measured value was evaluated on the following scale.

Grade 1: The surface temperature of the heater is 51.5° C. or above

Grade 2: The surface temperature of the heater is 51.0° C. or above and below 51.5° C.

Grade 3: The surface temperature of the heater is 50.5° C. or above and below 51.0° C.

Grade 4: The surface temperature of the heater is 50° C. or able and below 50.5° C.

Grade 5: The surface temperature of the heater is below 50° C.

<Evaluation of Reworkability>

The reworkability (removability) of each graphite composite film was evaluated. In the same manner as described in the heat dissipation test, the graphite composite film and a SUS plate were bonded together, and were left in an environment in which room temperature was 23° C. and humidity was 50% for 10 minutes from the bonding. Next, a peeling test (rework operation) was performed in the same environment. The reworkability was evaluated on the following scale. The measurement was performed 10 times, and the most frequent grade was used as the measurement result.

Grade 1: The graphite composite film is broken when subjected to a rework operation, and 50% or more of the graphite composite film remains unremoved on the SUS plate after one rework operation.

Grade 2: The graphite composite film is broken when subjected to a rework operation, and 10% or more and less than 50% of the graphite composite film remains unremoved on the SUS plate after one rework operation.

Grade 3: The graphite composite film is not broken when subjected to a rework operation, or, even if it is broken, only less than 10% of the graphite composite film remains unremoved on the SUS plate after one rework operation.

<Cost for Adhesive Layer>

The cost for an adhesive layer was evaluated on the basis of the cost per unit area (cm²). The cost per unit area was obtained by dividing the cost for the material for the adhesive layer necessary for producing one piece of graphite composite film by the area of the graphite composite film. The cost for an adhesive layer per unit area of an existing graphite composite film of Comparative Example 1 was assumed to be 1 (standard) and, on the basis of this standard, the costs for other Examples, Comparative Examples, and Reference Examples were calculated.

Grade 1: cost is greater than 1.3

Grade 2: cost is greater than 1.2 and 1.3 or less

Grade 3: cost is greater than 1.1 and 1.2 or less

Grade 4: cost is greater than 1 and 1.1 or less

Grade 5: cost is 1 or less

<Adhesion Stability>

The adhesion stability of each graphite composite film was evaluated. A PET separator was removed from the graphite composite film, and a SUS plate having a size of 100 mm×100 mm and a thickness of 2 mm and the graphite composite film were bonded together with the use of a laminator in a manner such that the SUS plate and the exposed adhesive face of an adhesive layer were brought into contact with each other in one go. The bonded stack was left in an environment in which room temperature was 23° C. and humidity was 50% for one day from the bonding. Next, a 1 cm cut was made through all the layers of the bonded stack, and the cut face was checked for delamination. Specifically, the cut face was checked for delamination and, if there was delamination, the maximum length of the delaminated portion was measured (in the case of an oval shape, the longest distance of a raised bump was measured).

The adhesion stability was evaluated on the following scale. The measurement was performed three times and the most frequent grade was used as the measurement result.

Grade 1: There is a delaminated portion with the maximum length of 1 mm or greater

Grade 2: There is a delaminated portion with the maximum length of 0.5 mm or greater and 1 mm or less

Grade 3: There is a delaminated portion with the maximum length of 0.5 mm or less

Grade 4: There are no delaminated portions

<Recap>

The results of the evaluations of the graphite composite films shown in Tables 4 and 5 demonstrate that the graphite composite films of Examples 1 to 7 and 34, the graphite composite films of Examples 8 to 13, 29 to 33, and 36, the graphite composite films of Examples 14 to 18 and 35, the graphite composite films of Examples 19 to 25, and the graphite composite films of Examples 26 to 28 of embodiments of the present invention can each reduce bubble entrapment between itself and an adherend when bonded to the adherend without impairing its heat dissipation ability and also have excellent adhesiveness and reworkability. The graphite composite films of Examples 1 to 7 and 34 include an adhesive layer on which a projection/recess structure has been formed by a method by which an adhesive solution is applied (or applied by printing). The graphite composite films of Examples 8 to 13, 29 to 33, and 36 include an adhesive layer on which a projection/recess structure has been formed by a method by which an adhesive solution is applied on a separator with a projection/recess structure at its surface to form a film and thereby an imprint of the projection/recess structure is formed. The graphite composite films of Examples 14 to 18 and 35 include an adhesive layer on which a projection/recess structure has been formed by a method by which the surface, which has a projection/recess structure, of a separator is brought into contact with an adhesive layer and thereby an imprint of the projection/recess structure is formed. The graphite composite films of 19 to 25 include an adhesive layer on which a projection/recess structure has been formed by a method by which the adhesive layer is formed on a graphite film with a projection/recess structure at its surface and thereby the projection/recess structure of the graphite film are caused to appear at the surface of the adhesive layer. The graphite composite films of Examples 26 to 28 include an adhesive layer on which a projection/recess structure has been formed by a method which is the combination of a method by which an adhesive layer with a projection/recess structure and a graphite film are stacked together and the method by which an adhesive layer is formed on a graphite film with a projection/recess structure at its surface and thereby the projection/recess structure of the graphite film is caused to appear at the surface of the adhesive layer.

The results of Reference Example 1, in which the graphite composite film was prepared in the same manner as described in Comparative Example 1 except that the cut size was 40 mm×60 mm, demonstrate that the concern of bubbles between the adherend and the graphite composite film does not occur at all when the graphite composite film is small in size. A graphite composite film of an embodiment of the present invention functions effectively to solve the bubble issue especially when the graphite composite film has a size of 25 cm² or greater.

Furthermore, the results of Reference Example 2, in which the graphite composite film was prepared in the same manner as described in Example 29 except that the cut size was 15 mm×15 mm, demonstrate that a graphite composite film small in size has a poor result in heat dissipation test. This demonstrates that a graphite composite film of an embodiment of the present invention shows high heat dissipating effects especially when the graphite composite film has a size of 3 cm² or greater.

Among Examples 1 to 7, the graphite composite films obtained in Examples 1, 3, 4, and 6 are particularly superior in that these graphite composite films have excellent results both in the bubble evaluation and the evaluation in the heat dissipation test. Such results demonstrate that, for higher heat dissipation ability and significantly less bubbles to be both achieved, it is more preferable that the adhesive parts occupy 50% or greater and 85% or less of the total area of the adhesive layer, that the “distance between island-like projections” be 0.1 mm or greater, or that the pitch of grooves in a lattice-like pattern be 0.1 mm or greater.

Among Examples 8 to 13, the graphite composite films obtained in Examples 8 and 10 are particularly superior in that these graphite composite films have excellent results both in the bubble evaluation and the evaluation in the heat dissipation test. Such results demonstrate that, for higher heat dissipation ability and significantly less bubbles to be both achieved, it is more preferable that the grooves have a depth of 0.5 μm or greater, that the grooves have a pitch of 0.15 μm or greater, or that the adhesive layer have a thickness of 10 μm or less.

Among Examples 14 to 18, the graphite composite films obtained in Examples 14, 16, and 17 are particularly superior in that these graphite composite films have excellent results both in the bubble evaluation and the evaluation in the heat dissipation test. Such results demonstrate that, for higher heat dissipation ability and significantly less bubbles to be both achieved, it is more preferable that a surface, which has a projection/recess structure, of a separator for use in forming an imprint of the projection/recess structure in an adhesive layer have a surface roughness that is 0.30 μm or greater and 0.70 μm or less in Ra and that is 2.90 μm or greater and 5.10 μm or less in Rz.

Among Examples 19 to 25, the graphite composite films obtained in Examples 19, 21, and 22 are particularly superior in that these graphite composite films have excellent results both in the bubble evaluation and the evaluation in the heat dissipation test. Such results demonstrate that, for higher heat dissipation ability and significantly less bubbles to be both achieved, it is more preferable that a surface, which has a projection/recess structure, of a graphite film used to form a projection/recess structure at a surface of an adhesive layer by causing the projection/recess structure of the graphite film to appear at the surface of the adhesive layer have a surface roughness that is 0.80 μm or greater and 1.30 μm or less in Ra and that is 3.20 μm or greater and 4.70 μm or less in Rz.

The results also showed that, even when an adhesive and a graphite film, which have excellent effects in Production Method 1 and Production Method 2 respectively, are used in combination like Examples 26 to 28, the adhesiveness and heat dissipation ability may sometimes deteriorate. This demonstrates that the objects of embodiments of the present invention cannot be achieved by simply selecting an adhesive having an excellent adhesion force and a highly heat-dissipating graphite film on the basis of previous findings.

Examples 29 to 33 and 36 provide, as with Examples 8 to 13, graphite composite films of embodiments of the present invention which include an adhesive layer on which a projection/recess structure has been formed by a method by which an adhesive solution is applied on a separator with a projection/recess structure at its surface to form a film and thereby an imprint of the projection/recess structure is formed in the film. Examples 29 to 33, in which the graphite film is a graphite laminate, are different from Examples 8 to 13, in which the graphite film is constituted by a single-layer graphite sheet. In comparison with a graphite film constituted by a thinner single-layer graphite sheet, a graphite film constituted by a graphite laminate often has a thickness as large as 90 μm or greater. On the other hand, Example 36 is the same as Examples 8 to 13 in that it uses a single-layer graphite film but is different from Examples 8 to 13 in that the graphite film has a thickness as large as 90 μm or greater because Examples 8 to 13 use a thinner graphite film. Especially when a graphite film has a thickness of 90 μm or greater like this, an issue arises in which the graphite film becomes more resilient and decreases in ability to stick to the adherend to which it is bonded, and thus the graphite film and the adherend trap bubbles between them more readily. In this regard, the results showed that the use of an adhesive layer of an embodiment of the present invention can prevent or reduce the bubble entrapment.

Example 34 provides, as with Examples 1 to 7, a graphite composite film of an embodiment of the present invention which includes an adhesive layer on which a projection/recess structure has been formed by a method by which an adhesive solution is applied (or applied by printing). Example 34, in which the graphite film is constituted by a graphite laminate, is different from Examples 1 to 7 in which the graphite film is constituted by a single-layer graphite sheet. The results also showed that Example 34 also can reduce bubble entrapment, as with the results of Examples 29 to 33 and 36.

Example 35 provides, as with Examples 14 to 18, a graphite composite film of an embodiment of the present invention which includes an adhesive layer on which a projection/recess structure has been formed by a method by which a surface, which has a projection/recess structure, of a separator is brought into contact with the adhesive layer and thereby an imprint of the projection/recess structure is formed in the adhesive layer. Example 35, in which the graphite film is constituted by a graphite laminate, is different from Examples 14 to 18 in which the graphite film is constituted by a single-layer graphite sheet. The results also showed that Example 35 can also reduce bubble entrapment, as with the results of Examples 29 to 33 and 36.

When a graphite film has a volume of 50 mm³ or greater, it becomes difficult to solve an issue in which the graphite film becomes more resilient and decreases in ability to stick to the adherend to which it is bonded, and thus the graphite film and the adherend trap bubbles between them more readily. Especially in the case of a graphite film constituted by a graphite laminate composed of two or more graphite sheets, it is important to solve this issue. In this regard, the results showed that the use of an adhesive layer of an embodiment of the present invention can solve this issue in Examples 1 to 35, in which the graphite film has a volume of 50 mm³ or greater. Especially in the case where the graphite film is a graphite laminate constituted by two or more graphite sheets, the volume tends to increase and thus the use of an adhesive layer of an embodiment of the present invention is particularly effective.

Furthermore, the results of the evaluation of adhesion stability shown in Tables 4 and 5 demonstrate that Examples 8 to 25, 27 to 33, 35, and 36, in which the area of the graphite film covered with an adhesive is 100% of the total area of the graphite film, showed better adhesion stability of the graphite composite film with respect to an adherend. Similarly, the results also demonstrate that Examples 1 to 7, in which the area of the graphite film covered with an adhesive is 35% or greater and less than 100% of the total area of the graphite film, showed better adhesion stability than Comparative Examples 2 and 3 in which the area of the graphite film covered with an adhesive is less than 35% of the total area of the graphite film.

### Production of Heat Dissipating Component

### Example 37

A heat dissipating component was created from the graphite composite film obtained in Example 1. Specifically, a PET separator was removed from the graphite composite film, and a SUS plate having a size of 70 mm×100 mm and a thickness of 0.2 mm and the graphite composite film were bonded together with the use of a laminator in a manner such that the SUS plate and the exposed adhesive face of an adhesive layer were brought into contact with each other in one go, such that a heat dissipating component was produced. It is noted here that the graphite composite film has a protective layer and an application layer stacked together on the surface of the graphite film opposite the SUS plate.

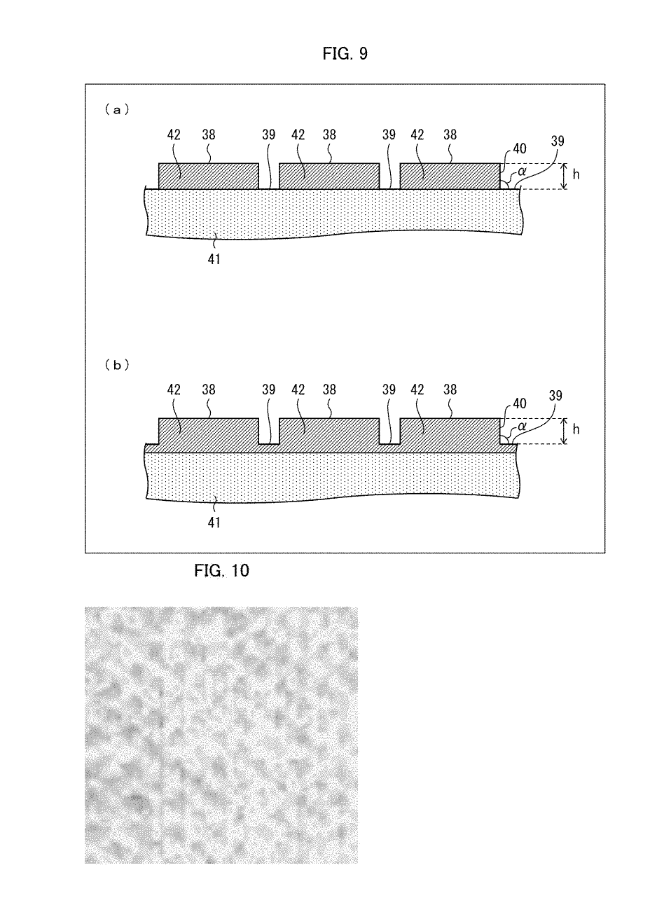

The application layer was removed from the obtained heat dissipating component, and the heat dissipating component was observed from the protective layer side. FIG. 10 shows how the heat dissipating component looks when viewed from the protective layer side. As is clear from FIG. 10, it was confirmed that the heat dissipating component had, at the surface of the graphite film opposite the SUS plate, a projection/recess structure appeared due to a projection/recess structure of the adhesive layer.

### Example 38

A heat dissipating component was created from the graphite composite film obtained in Example 29. Specifically, a PET separator was removed from the graphite composite film, and a SUS plate having a size of 70 mm×100 mm and a thickness of 0.2 mm and the graphite composite film were bonded together with the use of a laminator in a manner such that the SUS plate and the exposed adhesive face of an adhesive layer were brought into contact with each other in one go, such that a heat dissipating component was produced. It is noted here that the graphite composite film has a protective layer and an application layer stacked together on the surface of the graphite film opposite the SUS plate.

The heat dissipating component thus obtained was cut in a direction perpendicular to the surfaces of the graphite composite film, and the cut face was observed. The observation showed that, in the cut face, the adhesive layer, which resides between the SUS plate and the graphite film, of the heat dissipating component has a projection/recess structure at its surface facing the SUS plate.

In summary, the results demonstrated that all Examples, in comparison with Comparative Examples 1 to 3, bring about the effect that bubble entrapment between an adherend and the graphite composite film can be reduced when the graphite composite film is bonded to the adherend without impairing the heat dissipation ability of the graphite composite film.

### INDUSTRIAL APPLICABILITY

A graphite composite film of an embodiment of the present invention can reduce bubble entrapment between itself and an adherend when bonded to the adherend without impairing its heat dissipation ability. Therefore, the graphite composite film of an embodiment of the present invention can be suitably used as a heat dissipating component such as a heat dissipating film, a heat spreader material, or the like in the fields of electronic devices, precision devices, and the like.

### REFERENCE SIGNS LIST

1 Heat treatment apparatus
2 Polymeric film
3 Heating chamber
4 Graphite jig
5 Carbonized film
6 Graphitization furnace
7 Direction of gravitational force
8 Separator
9 Adhesive solution
10 Gravure roll of gravure coater
11 Squeegee
12 Stack obtained using dot printer
13 Stack
14 Separator
15 First adhesive layer
16 Base
17 Second adhesive layer (island-like projections)
19 Embossed separator
20 Adhesive solution
21 Squeegee
22 Second adhesive layer
23 Base
24 First adhesive layer
25 Separator
26 Separator
27 Adhesive layer without projection/recess structure
28 Base
29 Adhesive layer (first adhesive layer)
30 Separator
31 Embossed separator
32 Second adhesive layer
33 SUS plate
34 Adhesive layer
35 Graphite film
36 Protective layer
37 Heat generating component
38 Top face of projection
39 Bottom of recess
40 Side wall of island-like projection
41 Graphite film
42 Adhesive
43 Second adhesive layer
44 Base
45 First adhesive layer

1. A graphite composite film comprising: a graphite film; and an adhesive layer in contact with the graphite film, wherein
an area of the graphite film covered with an adhesive is 35% or more and 100% or less of a total area of the graphite film, and
the adhesive layer has a projection/recess structure at a surface thereof which faces away from the graphite film.

2. The graphite composite film according to claim 1, wherein a surface roughness in Ra of the surface of the adhesive layer, the surface having the projection/recess structure, is 0.19 μm or greater and 10 μm or less.

3. The graphite composite film according to claim 1, wherein a surface roughness in Rz of the surface of the adhesive layer, the surface having the projection/recess structure, is 1.6 μm or greater and 100 μm or less.

4. The graphite composite film according to claim 1, wherein the adhesive layer has a thickness of 1.00 μm or greater and 20.00 μm or less.

5. The graphite composite film according to claim 1, wherein the projection/recess structure at the surface of the adhesive layer is defined by grooves in a lattice-like pattern or a striped pattern or by separate island-like projections.

6. The graphite composite film according to claim 5, wherein the grooves in a lattice-like pattern or a striped pattern have a pitch of 0.05 mm or greater and 2.0 mm or less.

7. The graphite composite film according to claim 1, wherein:
the adhesive layer includes a first adhesive layer, a base, and a second adhesive layer;
the first adhesive layer, the base, and the second adhesive layer of the adhesive layer are stacked on the graphite film in this order from the graphite film;
the area of the graphite film covered with the adhesive in the second adhesive layer is 35% or more and 100% or less of the total area of the graphite film; and
the adhesive layer has the projection/recess structure at a surface of the second adhesive layer, the surface facing away from the base.

8. The graphite composite film according to claim 7, wherein:
the second adhesive layer is constituted by adhesive parts disposed on the base; and
the projection/recess structure at the surface of the adhesive layer includes projections which are constituted by the adhesive parts and recesses in which there is no adhesive and the base is exposed.

9. The graphite composite film according to claim 8, wherein the adhesive parts occupy 35% or more of a total area of the adhesive layer.

10. The graphite composite film according to claim 8, wherein, assuming that the adhesive parts are regularly arranged projections in the form of polygonal, rod-shaped, and/or strip-shaped islands, a distance between mutually facing edges of adjacent ones of the projections is 0.01 mm or greater.

11. The graphite composite film according to claim 1, wherein a peel strength between the graphite composite film and SUS is 4.0 N/25 mm or greater and 12.0 N/25 mm or less.

12. The graphite composite film according to claim 1, which has an area of 3 cm² or greater.

13. The graphite composite film according to claim 1, wherein the graphite film has a thickness of 90 μm or greater.

14. The graphite composite film according to claim 1, wherein: the graphite film is a graphite laminate including alternately stacked graphite sheets and bonding layers; and the number of the graphite sheets in the graphite laminate is three or more.

15. The graphite composite film according to claim 1, wherein the graphite film has a volume of 50 mm³ or greater.

16. A method for producing a graphite composite film that includes a graphite film and an adhesive layer in contact with the graphite film, the method comprising stacking the adhesive layer and the graphite film together in a manner such that:
an area of the graphite film covered with an adhesive is 35% or more and 100% or less of a total area of the graphite film; and
at least one surface of the adhesive layer, the at least one surface having a projection/recess structure thereon, faces away from the graphite film.

17. A method for producing a graphite composite film that includes a graphite film and an adhesive layer in contact with the graphite film, the method comprising:
preparing the adhesive layer which has a projection/recess structure at at least one surface thereof by forming an imprint of a projection/recess structure of a surface of a separator in the at least one surface of the adhesive layer; and
stacking the adhesive layer and the graphite film together in a manner such that the at least one surface having the projection/recess structure thereon faces away from the graphite film.

18. The method according to claim 17, wherein a surface roughness of the surface of the separator, the surface having the projection/recess structure, is 0.06 μm or greater and 1.00 μm or less in Ra and is 0.3 μm or greater and 10.0 μm or less in Rz.

19. The method according to claim 17, wherein the imprint of the projection/recess structure of the surface of the separator is formed by applying an adhesive solution to the surface of the separator to form a film.

20. The method according to claim 17, wherein the imprint of the projection/recess structure of the surface of the separator is formed in the at least one surface of the adhesive layer by bringing the separator into contact with the adhesive layer which contains 5% or less of a solvent remaining therein.

21. A method for producing a graphite composite film that includes a graphite film and an adhesive layer in contact with the graphite film, the method comprising:
forming a projection/recess structure at a surface of the adhesive layer by forming the adhesive layer on the graphite film which has a projection/recess structure at a surface thereof to thereby cause the projection/recess structure of the graphite film to appear at the surface of the adhesive layer.

22. The method according to claim 21, wherein a surface roughness of the surface of the graphite film, the surface having the projection/recess structure, is 0.55 μm or greater and 1.70 μm or less in Ra and is 2.3 μm or greater and 6.00 μm or less in Rz.

23. The method according to claim 21, wherein the graphite film has a thickness of 5 μm or greater and 120 μm or less.

24. The method according to claim 21, wherein a surface roughness of the surface of the adhesive layer, the surface having the projection/recess structure, is 0.8 μm or less in Ra and is 4.5 μm or less in Rz.

25. A heat dissipating component comprising a graphite composite film, the graphite composite film including: a graphite film; and an adhesive layer in contact with the graphite film, wherein the area of the graphite film covered with an adhesive is 35% or more and 100% or less of the total area of the graphite film, and the adhesive layer has a projection/recess structure at a surface thereof which faces away from the graphite film.

26. The heat dissipating component according to claim 25, further comprising an adherend bonded to the graphite composite film.

27. The heat dissipating component according to claim 26, further comprising a protective layer disposed on a surface of the graphite composite film, the surface facing away from the adherend, and the protective layer having a surface with a surface roughness that is 0.15 μm or greater and 10 μm or less in Ra and that is 1.0 μm or greater and 100 μm or less in Rz.
